(19) United States
(12) Patent Application Publication
(10) Pub. No.: US 2026/0353925 A1
(43) Pub. Date: Nov. 5, 2026

(54) DISPLAY PANEL AND DISPLAY DEVICE

(71) Applicant: XIAMEN TIANMA DISPLAY TECHNOLOGY CO., LTD., Xiamen (CN)

(72) Inventors: Yongxiang LIN, Xiamen (CN); Jinjin YANG, Xiamen (CN); Yong YUAN, Xiamen (CN)

(73) Assignee: XIAMEN TIANMA DISPLAY TECHNOLOGY CO., LTD., Xiamen (CN)

(21) Appl. No.: 19/725,024

(22) Filed: Jun. 30, 2026

(30) Foreign Application Priority Data
Mar. 6, 2026 (CN) 202610274655.0

(51) Int. Cl. H10K 59/121; H10H 29/01; H10H 29/32; H10H 29/49; H10K 59/12; H10K 59/131; H10K 102/00

(52) U.S. Cl. CPC H10K 59/1213; H10H 29/012; H10H 29/32; H10H 29/49; H10K 59/1201; H10K 59/1315; H10K 2102/351

(57) ABSTRACT

A display panel includes a substrate and a circuit functional layer on a side of the substrate. The circuit functional layer includes multiple pixel circuits in a display area. At least part of the pixel circuits includes a first transistor and a light-emitting element. The first transistor includes a first active structure, a first gate and a second gate. The circuit functional layer further includes first conductive structures on a side of the second gate away from the substrate. The first conductive structure includes a first connection portion. Along a direction perpendicular to a plane where the substrate is located, the first connection portion overlaps an overlapping area of the first gate and the second gate of one first transistor, and connects the first gate and the second gate of the one first transistor.

### CROSS REFERENCE OF RELATED APPLICATION

This application claims priority to Chinese Patent Application No. 202610274655.0, filed on Mar. 6, 2026, which is hereby incorporated by reference in its entirety.

### FIELD

The present application relates to the field of display technology, and in particular, to a display panel and a display device.

### BACKGROUND

With the development of multimedia technology, the importance of display products has steadily increased, but the performance of current display products still needs to be improved.

### SUMMARY

The present application provides a display panel and a display device, to improve the performance of display products.

According to one aspect of the present application, a display panel is provided. The display panel includes: a substrate, and a circuit functional layer on a side of the substrate.

The circuit functional layer includes multiple pixel circuits in a display area.

At least part of the multiple pixel circuits includes a first transistor and a light-emitting element.

The first transistor includes a first active structure, a first gate and a second gate, where the first gate is located on a side of the first active structure close to the substrate, and the second gate is located on a side of the first active structure away from the substrate.

The circuit functional layer further includes first conductive structures on a side of the second gate away from the substrate.

A first conductive structure of the first conductive structures includes a first connection portion; along a direction perpendicular to a plane where the substrate is located, the first connection portion overlaps an overlapping area of the first gate and the second gate of one first transistor, and the first connection portion connects the first gate and the second gate of the one first transistor.

According to another aspect of the present application, a display panel is provided. The display panel includes: a substrate, and a circuit functional layer on a side of the substrate.

The circuit functional layer includes multiple pixel circuits in a display area.

At least part of the multiple pixel circuits include a second transistor and a light-emitting element.

The second transistor includes a second active structure, a third gate and a fourth gate, where the third gate is located on a side of the second active structure close to the substrate, and the fourth gate is located on a side of the second active structure away from the substrate.

The circuit functional layer further includes a second conductive structure on a side of the fourth gate away from the substrate.

The second conductive structure includes a second connection portion; along a direction perpendicular to a plane where the substrate is located, the second connection portion overlaps an overlapping area of the third gate and the second active structure of one second transistor, and the second connection portion connects the third gate and the second active structure of the one second transistor.

According to yet another aspect of the present application, a display device is provided. The display device includes any one of the display panels as described above.

The content described in this section is not intended to identify the key or important features of embodiments of the present application, nor is it used to limit the scope of the present application. Other features of the present application will become easy to understand through the following description.

### BRIEF DESCRIPTION OF THE DRAWINGS

To more clearly illustrate the embodiments of the present application, the following briefly introduces the drawings that need to be used in the description of the embodiments. In one embodiment, the drawings described below are only some embodiments of the present application.

FIG. 1 is a first schematic top view of a display panel according to an embodiment of the present application;

FIG. 2 is a first schematic diagram of a film structure of a display panel according to an embodiment of the present application;

FIG. 3 is a first schematic top view of a first transistor according to an embodiment of the present application;

FIG. 4 is a second schematic top view of a display panel according to an embodiment of the present application;

FIG. 5 is a second schematic diagram of a film structure of a display panel according to an embodiment of the present application;

FIG. 6 is a first schematic diagram of a circuit structure of a pixel circuit according to an embodiment of the present application;

FIG. 7 is a third schematic diagram of a film structure of a display panel according to an embodiment of the present application;

FIG. 8 is a fourth schematic diagram of a film structure of a display panel according to an embodiment of the present application;

FIG. 9 is a second schematic top view of a first transistor according to an embodiment of the present application;

FIG. 10 is a schematic diagram of a film structure of a first transistor according to an embodiment of the present application;

FIG. 11 is a fifth schematic diagram of a film structure of a display panel according to an embodiment of the present application;

FIG. 12 is a third schematic top view of a first transistor according to an embodiment of the present application;

FIG. 13 is a first flowchart of a method for manufacturing a display panel according to an embodiment of the present application;

FIG. 14 is a sixth schematic diagram of a film structure of a display panel according to an embodiment of the present application;

FIG. 15 is a first schematic top view of a second transistor according to an embodiment of the present application;

FIG. 16 is a seventh schematic diagram of a film structure of a display panel according to an embodiment of the present application;

FIG. 17 is a second schematic diagram of a circuit structure of a pixel circuit according to an embodiment of the present application;

FIG. 18 is an eighth schematic diagram of a film structure of a display panel according to an embodiment of the present application;

FIG. 19 is a second schematic top view of a second transistor according to an embodiment of the present application;

FIG. 20 is a ninth schematic diagram of a film structure of a display panel according to an embodiment of the present application;

FIG. 21 is a third schematic top view of a second transistor according to an embodiment of the present application;

FIG. 22 is a second flowchart of a method for manufacturing a display panel according to an embodiment of the present application;

FIG. 23 is a tenth schematic diagram of a film structure of a display panel according to an embodiment of the present application;

FIG. 24 is an eleventh schematic diagram of a film structure of a display panel according to an embodiment of the present application;

FIG. 25 is a schematic structural diagram of a display device according to an embodiment of the present application.

### DETAILED DESCRIPTION OF THE EMBODIMENTS

To enable those to better understand the solutions of the present application, the embodiments of the present application will be clearly and completely described below in conjunction with the drawings in the embodiments of the present application. In one embodiment, the described embodiments are only a part of the embodiments of the present application, rather than all the embodiments.

The terms “first”, “second”, etc. in the description and claims of the present application and the above drawings are used to distinguish similar objects and are not necessarily used to describe a specific order or sequence. The data used in one embodiment, can be interchanged under appropriate circumstances, and the embodiments of the present application described here can be implemented in an order other than those illustrated or described here. In addition, the terms “include” and “have” and any of their variations are intended to cover non-exclusive inclusion, for example, a process, method, system, product or device that includes a series of steps or units is not necessarily limited to those steps or units explicitly listed, but may include other steps or units not explicitly listed or inherent to these processes, methods, products or devices.

A display panel is provided according to an embodiment of the present application. The display panel includes: a substrate, and a circuit functional layer on a side of the substrate. The circuit functional layer includes multiple pixel circuits in a display area. At least part of the pixel circuits include a first transistor and a light-emitting element. The first transistor includes a first active structure, a first gate and a second gate. The first gate is located on a side of the first active structure close to the substrate, and the second gate is located on a side of the first active structure away from the substrate. The circuit functional layer further includes a first conductive structure located on a side of the second gate away from the substrate. The first conductive structure includes a first connection portion. Along a direction perpendicular to a plane where the substrate is located, the first connection portion overlaps an overlapping area of the first gate and the second gate of one first transistor, and the first connection portion connects the first gate and the second gate of the one first transistor; and/or, at least part of the pixel circuits include a second transistor and a light-emitting element. The second transistor includes a second active structure, a third gate and a fourth gate. The third gate is located on a side of the second active structure close to the substrate, and the fourth gate is located on a side of the second active structure away from the substrate. The circuit functional layer further includes a second conductive structure on a side of the fourth gate away from the substrate. The second conductive structure includes a second connection portion. Along a direction perpendicular to a plane where the substrate is located, the second connection portion overlaps an overlapping area of the third gate and the second active structure of one second transistor, and the second connection portion connects the third gate and the second active structure of the one second transistor.

With the above embodiments, the transistor with a dual-gate structure is arranged in the pixel circuit. In the first transistor, the first connection portion of the first conductive structure connects the first gate and the second gate of the same first transistor, to electrically connect the first gate and the second gate of this first transistor, which is beneficial to increase the on-state current of the first transistor, improve the switching speed of the first transistor, and realize high-frequency refresh. In addition, along the direction perpendicular to the plane where the substrate is located, the first connection portion of the first conductive structure overlaps the overlapping area of the first gate and the second gate of the same first transistor, to overlap a first extension area of the first gate and a second extension area of the second gate along the direction perpendicular to the plane where the substrate is located, which can reduce the space occupied by the extension areas of the first transistor in the direction perpendicular to the plane where the substrate is located and improve the performance of the first transistor, thereby reducing the space occupied by the pixel circuit and improve the resolution and thinning of the display panel.

The second transistor with a dual-gate structure is arranged in the pixel circuit. In the second transistor, the second connection portion of the second conductive structure connects the third gate and the second active structure of the same second transistor, to electrically connect the third gate and a source area or a drain area of the second active structure of this second transistor, which is beneficial to suppress the threshold voltage shift of the second transistor, improve its working stability, extend its service life, and thus improve the display effect and reliability of the display panel 010. In addition, along the direction perpendicular to the plane where the substrate is located, the second connection portion of the second conductive structure overlaps the overlapping area of the third gate and the second active structure of the same second transistor, to overlap a first extension area of the third gate and a third extension area of the second active structure along the direction perpendicular to the plane where the substrate is located, which can reduce the space occupied by the extension areas of the second transistor in the direction perpendicular to the plane where the substrate is located and improve the performance of the second transistor, thereby reducing the space occupied by the pixel circuit and improve the resolution and thinning of the display panel.

In addition, when the display panel is a transparent display panel or a partially transparent display panel, it is also beneficial to improve the light transmittance of the display panel.

The above is the core idea of the present application. The embodiments of the present application will be clearly and completely described below in conjunction with the drawings in the embodiments of the present application.

The implementations provided by the embodiments of the present application can be combined with each other if there is no contradiction.

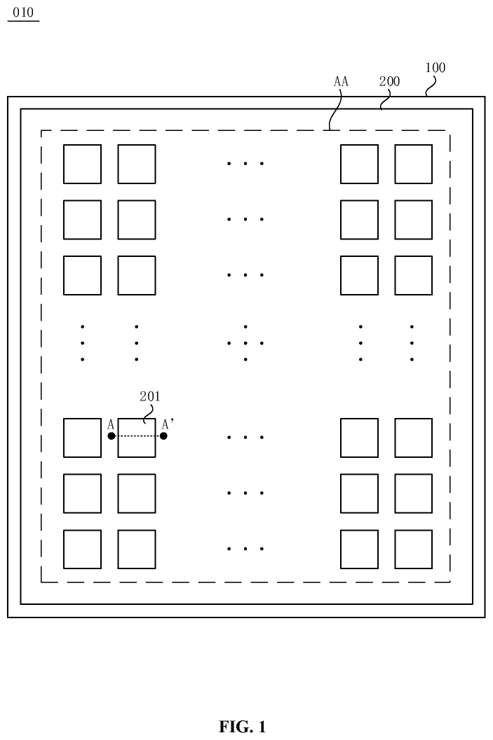

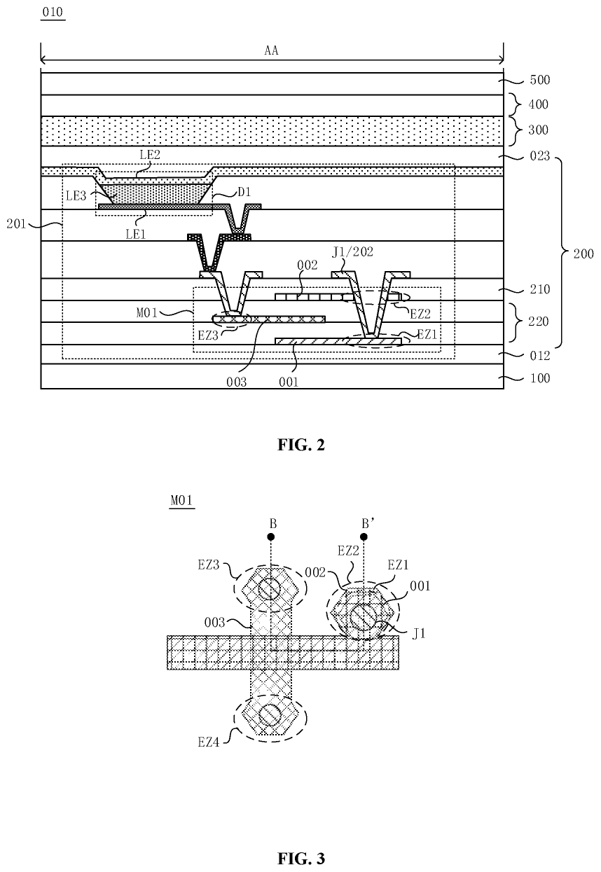

FIG. 1 is a first schematic top view of a display panel according to an embodiment of the present application, and FIG. 2 is a first schematic diagram of a film structure of a display panel according to an embodiment of the present application. FIG. 2 may be a schematic cross-sectional view of the display panel 010 along the dashed line A-A′ in FIG. 1. Referring to FIG. 1 and FIG. 2, the display panel 010 includes a substrate 100 and a circuit functional layer 200 on a side of the substrate 100. The circuit functional layer 200 includes multiple pixel circuits 201 in a display area AA. At least part of the pixel circuits 201 includes a first transistor M01 and a light-emitting element D1. The first transistor M01 includes a first gate 001, a second gate 002 and a first active structure 003. The first gate 001 is located on a side of the first active structure 003 close to the substrate 100, and the second gate 002 is located on a side of the first active structure 003 away from the substrate 100.

FIG. 3 is a first schematic top view of a first transistor according to an embodiment of the present application. The cross-sectional structure of the first transistor M01 along the dashed line B-B′ in FIG. 3 is shown in FIG. 2. Referring to FIG. 2 and FIG. 3, the circuit functional layer 200 further includes a first conductive structure 202 on a side of the second gate 002 away from the substrate 100. The first conductive structure 202 includes a first connection portion J1. Along the direction perpendicular to the plane where the substrate 100 is located, the first connection portion J1 overlaps an overlapping area of the first gate 001 and the second gate 002 of one first transistor M01, and the first connection portion J1 connects the first gate 001 and the second gate 002 of the one first transistor M01.

The substrate 100 includes a rigid substrate or a flexible substrate. The material of the rigid substrate includes, but is not limited to, glass, silicon and other materials. The material of the flexible substrate includes, but is not limited to, polyimide (PI), polyethylene terephthalate (PET), polymethyl methacrylate (PMMA) and other materials. The pixel circuit 201 in the display area AA includes, but is not limited to, a pixel circuit, such as 2T1C, 6T2C, 7T1C, 8T1C. The first transistor M01 may be any transistor in the pixel circuit 201. The first transistor M01 may be an LTPS-TFT or an IGZO-TFT. The first transistor M01 may be a P-type transistor, or an N-type transistor. The arrangement position, the material of the active structure and the channel type of the first transistor M01 in the pixel circuit 201 will not be limited in the embodiments of the present application. The light-emitting element D1 includes, but is not limited to, light-emitting structures such as OLED and LED.

In an embodiment, the first transistor M01 is a dual-gate transistor. The first gate 001 is a newly added gate of the first transistor M01, by which the first transistor M01 may have a better channel charge control capability. The second gate 002 is a driving gate of the first transistor M01. The on-off state of the first transistor M01 can be controlled by the potential of the second gate 002. The first conductive structure 202 can be used to transmit a gate driving signal, and provide the gate driving signal to the second gate 002 to control the potential of the second gate 002. The first connection portion J1 of the first conductive structure 202 can connect the second extension area EZ2 of the second gate 002, to realize reliable electrical connection between the first conductive structure 202 and the second gate 002.

Along the direction perpendicular to the plane where the substrate 100 is located, the first connection portion J1 of the first conductive structure 202 also connects the first extension area EZ1 of the first gate 001, to provide the gate driving signal to the first gate 001 by the first conductive structure 202 to control the potential of the first gate 001. In addition, the first gate 001 and the second gate 002 can be electrically connected through the first connection portion J1, and the potential of the first gate 001 and the potential of the second gate 002 are the same, which is beneficial to increase the on-state current of the first transistor M01 and improve the switching speed. In addition, along the direction perpendicular to the plane where the substrate 100 is located, the first connection portion J1 overlaps the overlapping area of the first gate 001 and the second gate 002 of the same first transistor M01. That is, the first connection portion J1 simultaneously overlaps the first extension area EZ1 of the first gate 001 and the second extension area EZ2 of the second gate 002. The newly added extension area (the first extension area EZ1) overlaps an original extension area (the second extension area EZ2). There is no need to additionally provide a space for overlapping the newly added gate (the first gate 001), which is beneficial to reduce the influence on the arrangement of the pixel circuit 201 in the display panel 010 while improving the performance of the first transistor M01, thereby improving the resolution and thinning, and avoiding increasing the space occupied by the extension area of the first transistor M01 in the direction perpendicular to the plane where the substrate 100 is located. The increased space may affect the arrangement of the pixel circuit 201 in the display panel 010 and not be conducive to improving the performance of the display panel.

Continuing to refer to FIG. 2 and FIG. 3, the first active structure 003 includes a third extension area EZ3 and a fourth extension area EZ4. The first transistor M01 includes four extension areas, i.e., the first extension area EZ1, the second extension area EZ2, the third extension area EZ3 and the fourth extension area EZ4. The vertical projections of the first extension area EZ1 on the plane where the substrate 100 is located overlaps that of the second extension area EZ2 on the plane where the substrate 100 is located, and the vertical projection of the first transistor M01 on the plane where the substrate 100 is located only occupies the space of three extension areas on the plane where the substrate 100 is located, which can effectively reduce the space occupation while improving the performance of the first transistor M01, and improving the performance of the display panel 010.

Exemplarily, the display panel 010 further includes a protective layer 012 arranged between the substrate 100 and the circuit functional layer 200 and adjacent to the substrate 100. The protective layer 012 includes, but is not limited to, film structures such as a barrier layer, a transition layer, a buffer layer, which can reduce or prevent foreign substances, moisture or external air from penetrating from the side of the substrate 100 away from the circuit functional layer 200, and provide a flat surface for the circuit functional layer 200.

In a process of manufacturing the first transistor M01 in the circuit functional layer 200, the first gate 001 can be formed first, then the first active structure 003 is formed, and finally the second gate 002 is formed. Along the direction perpendicular to the plane where the substrate 100 is located, a partial area of the overlapping area of the second gate 002 and the first gate 001 does not overlap the first active structure 003. In the partial area, the second extension area EZ2 and the first extension area EZ1 overlap, and both of the second extension area EZ2 and the first extension area EZ1 do not overlap the first active structure 003. This partial area can overlap the first connection portion J1 of the first conductive structure 202, that is, the second extension area EZ2 and the first extension area EZ1 both overlap the first connection portion J1 at this partial area.

After the first transistor M01 is manufactured, i.e., after the second gate 002 is formed, a first dielectric layer 210 can be formed on a side of the second gate 002 away from the substrate 100. Then, the first conductive structure 202 is formed on a side of the first dielectric layer 210 away from the substrate 100. The first connection portion J1 of the first conductive structure 202 can simultaneously connect the second extension area EZ2 of the second gate 002 and the first extension area EZ1 of the first gate 001.

After the first conductive structure 202 is formed, the light-emitting element D1 can be manufactured on a side of the first conductive structure 202 away from the substrate 100. The light-emitting element D1 includes a first electrode LE1, a second electrode LE2, and a light-emitting layer LE3 located between the first electrode LE1 and the second electrode LE2. The display panel 010 may further include structures such as an encapsulation layer 023, a touch functional layer 300, an optical functional layer 400, and a cover plate 500 located on the side of the light-emitting element D1 away from the substrate 100, which will not be described one by one in the embodiments of the present application.

It can also be understood that each of the pixel circuits 201 located in the display area AA in the circuit functional layer 200 may include the first transistor M01. In one embodiment, only a part of the pixel circuits 201 may include the first transistor M01. That is, the pixel circuits 201 located in a part of the display area AA in the circuit functional layer 200 do not include the first transistor M01, and the pixel circuits 201 located in a part of the display area AA in the circuit functional layer 200 include the first transistor M01. In one embodiment, the transistors in the pixel circuit 201 provided with the first transistor M01 in the circuit functional layer 200 may all be the first transistor M01. In other implementations, in the circuit functional layer 200, the transistors in the pixel circuit 201 provided with the first transistor M01 may partially be the first transistor M01. That is, in the circuit functional layer 200, the pixel circuit 201 provided with the first transistor M01 may further include other transistors different from the first transistor M01 in one or more of the film arrangement position, structure, material and connection method, such as the second transistor M02 provided later.

Along the direction perpendicular to the plane where the substrate 100 is located, the first extension area EZ1 of the first gate 001 and the second extension area EZ2 of the second gate 002 of the first transistor M01 overlap, and the first extension area EZ1 and the second extension area EZ2 both connect the first connection portion J1 of the first conductive structure 202. Regardless of which transistors in the display panel 010 are the first transistor M01, the first conductive structure 202 is provided directly above the side of the first transistor M01 away from the substrate 100, i.e., the overlapping area along the direction perpendicular to the plane where the substrate 100 is located. Along the direction perpendicular to the plane where the substrate 100 is located, the first connection portion J1 of the first conductive structure 202 overlaps both the first extension area EZ1 of the first gate 001 and the second extension area EZ2 of the second gate 002 of the same first transistor M01, which can improve the transistor performance, and can effectively reduce the space occupation and improve the performance of the display panel.

In the embodiments of the present application, the first transistor with a dual-gate structure is arranged in the pixel circuit. In the first transistor, the first connection portion of the first conductive structure connects the first gate and the second gate of the same first transistor, to electrically connect the first gate and the second gate of this first transistor, which is beneficial to increase the on-state current of the first transistor, improve the switching speed of the first transistor, and realize high-frequency refresh. In addition, along the direction perpendicular to the plane where the substrate is located, the first connection portion of the first conductive structure overlaps the overlapping area of the first gate and the second gate of the same first transistor, to overlap the first extension area of the first gate and the second extension area of the second gate along the direction perpendicular to the plane where the substrate is located, which can reduce the space occupied by the extension area of the first transistor in the direction perpendicular to the plane where the substrate is located while improving the performance of the first transistor, thereby reducing the space occupied by the pixel circuit. This arrangement is beneficial to improve the resolution and thinning of the display panel. In addition, when the display panel is a transparent display panel or a partially transparent display panel, it is also beneficial to improve the light transmittance of the display panel.

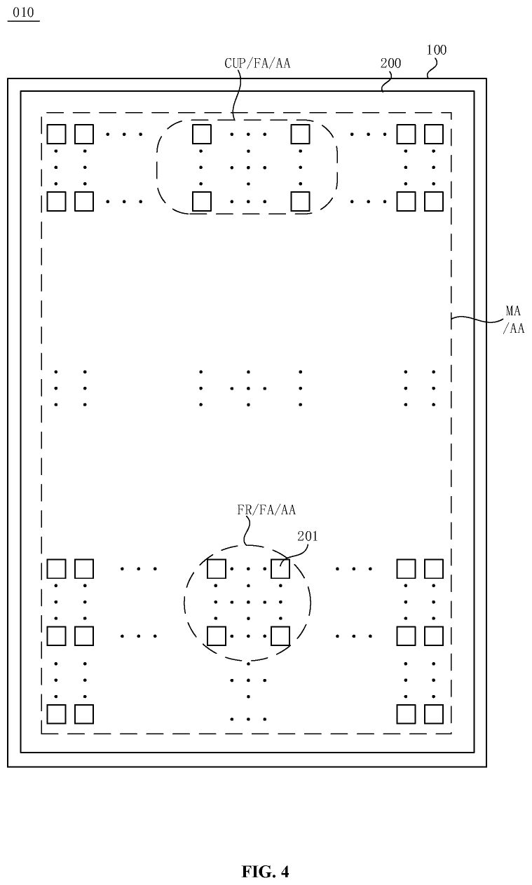

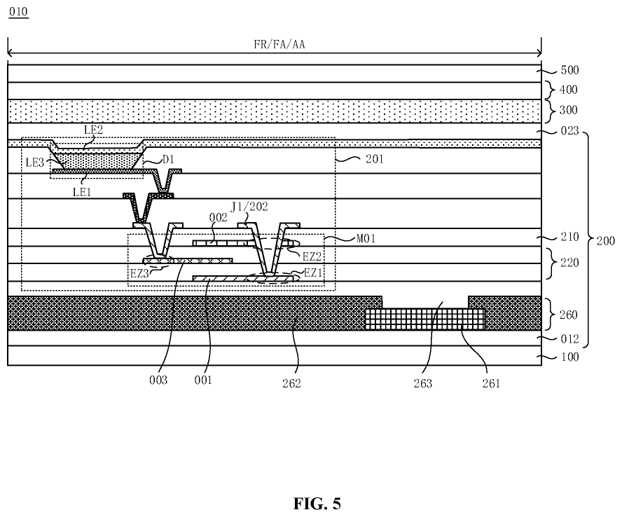

In an embodiment, FIG. 4 is a second schematic top view of a display panel according to an embodiment of the present application, and FIG. 5 is a second schematic diagram of a film structure of a display panel according to an embodiment of the present application. Referring to FIG. 4 and FIG. 5, the display area AA includes a functional device arrangement area FA and a main display area MA at least partially surrounding the functional device arrangement area FA. The functional device arrangement area FA includes a pixel circuit 201 and a functional device 261 on a side of the pixel circuit 201 close to the substrate 100. The circuit functional layer 200 in the functional device arrangement area FA includes the first transistors M01 and the first conductive structures 202. One first conductive structure of the first conductive structures connects the first gate 001 and the second gate 002 of the same first transistor M01.

The functional device arrangement area FA includes, but is not limited to, areas, such as, a camera under panel (CUP) area and a fingerprint reader FR area. When the functional device arrangement area FA is the CUP area, the functional device 261 may be an image sensor for performing functions, such as, image capturing, video recording, and facial recognition. When the functional device arrangement area FA is the fingerprint recognition FR area, the functional device 261 may be an optical sensor for performing fingerprint recognition. In one embodiment, along the direction perpendicular to the plane where the substrate 100 is located, the functional device 261 does not overlap the pixel circuit 201.

In an embodiment, taking the functional device arrangement area FA as the fingerprint recognition FR area as an example, referring to FIG. 5, the circuit functional layer 200 of the display panel 010 further includes a photosensitive layer 260 between the pixel circuit 201 and the substrate 100. The photosensitive layer 260 includes a functional device 261 (optical sensor) and a light guide layer 262 located on a side of the functional device 261 away from the substrate 100. The light guide layer 262 includes a light guide opening 263. The functional device 261 (optical sensor) can perform fingerprint recognition through the light transmitted by the light guide opening 263. The first transistor M01 and the first conductive structure 202 connecting the first gate 001 and the second gate 002 of the same first transistor M01 are arranged in the circuit functional layer 200 in the functional device arrangement area FA, to reduce the space occupied by the pixel circuit 201 in the functional device arrangement area FA, increase the light transmittance of the side of the photosensitive layer 260 away from the substrate in the functional device arrangement area FA, which is beneficial to improve the sensitivity and accuracy of fingerprint recognition.

In other implementations, the circuit functional layer in the main display area may also be provided with the first transistor and the first conductive structure connecting the first gate and the second gate of the same first transistor (not shown in FIG. 5).

In other embodiments, the first transistor M01 includes a driving transistor M3 and/or a switching transistor STFT. The driving transistor M3 is used to selectively provide a driving signal to the light-emitting element D1. The switching transistor STFT is used to selectively provide an electrical signal to the driving transistor M3 and/or the light-emitting element D1.

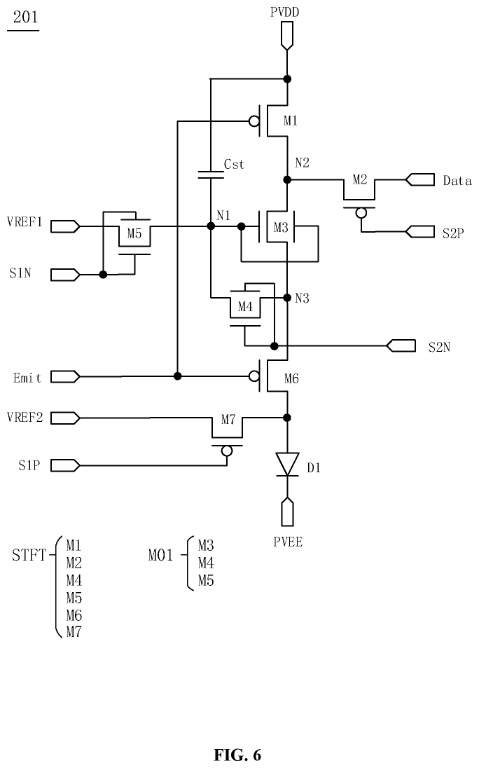

In an embodiment, FIG. 6 is a first schematic diagram of a circuit structure of a pixel circuit according to an embodiment of the present application. Referring to FIG. 6, the pixel circuit 201 is a 7T1C pixel circuit. The pixel circuit 201 may include a first light-emitting control transistor M1, a write transistor M2, a driving transistor M3, a compensation transistor M4, an initialization transistor M5, a second light-emitting control transistor M6, a reset transistor M7 and a storage capacitor Cst. The switching transistor STFT includes the first light-emitting control transistor M1, the write transistor M2, the compensation transistor M4, the initialization transistor M5, the second light-emitting control transistor M6 and the reset transistor M7. The driving transistor M3 and/or the switching transistor STFT in the pixel circuit 201 can be set as the first transistor M01 which is dual-gate transistors. Along the direction perpendicular to the plane where the substrate 100 is located, the first extension area EZ1 of the first gate 001 and the second extension area EZ2 of the second gate 002 overlap, both of which connect the first connection portion J1 of the first conductive structure 202. In one embodiment, the driving transistor M3, the compensation transistor M4 and the initialization transistor M5 in at least part of the pixel circuits 201 are the first transistor M01. In another embodiment, all transistors in at least part of the pixel circuits 201 are set as the first transistor M01. In yet another implementation, the driving transistor M3 in at least part of the pixel circuits 201 is the first transistor M01.

FIG. 6 only exemplarily shows a circuit structure of the pixel circuit 201, but is not limited thereto. It is sufficient as long as at least one of the driving transistor M3 and the switching transistor STFT in the pixel circuit 201 is the first transistor M01, and the first gate 001 and the second gate 002 of the first transistor M01 both connect the first connection portion J1 of the first conductive structure 202.

In an embodiment, the first active structure 003 of the first transistor M01 includes a metal oxide material.

The metal oxide material includes, but is not limited to, IGZO, for example, an oxide material selected from one or more of indium (In), gallium (Ga), tin (Sn), zirconium (Zr), hafnium (Hf), titanium (Ti) and zinc (Zn).

In an embodiment, the metal oxide material can be manufactured by a physical vapor deposition (PVD) technology, such as a magnetron sputtering method, without forming a crystal structure by crystallization, to obtain the metal oxide material with good uniformity, which is beneficial to improve the consistency of the performance of each pixel circuit 201. In addition, the manufacturing difficulty and manufacturing cost of the metal oxide material are low. By using the metal oxide material as the active structure, the leakage current can be reduced through material characteristics of the metal oxide material, such as, wide band gap and interface state density.

On the basis of the above embodiment, the first active structure 003 of the first transistor M01 is of a linear design. In this way, it is beneficial to reduce the channel width-to-length ratio and further reduce the space occupied by the first transistor M01. When the first active structure 003 includes the metal oxide material, the first active structure 003 has good uniformity, and the first transistor M01 has high mobility and low leakage current. It is not necessary to set a long channel width-to-length ratio to meet the use requirements.

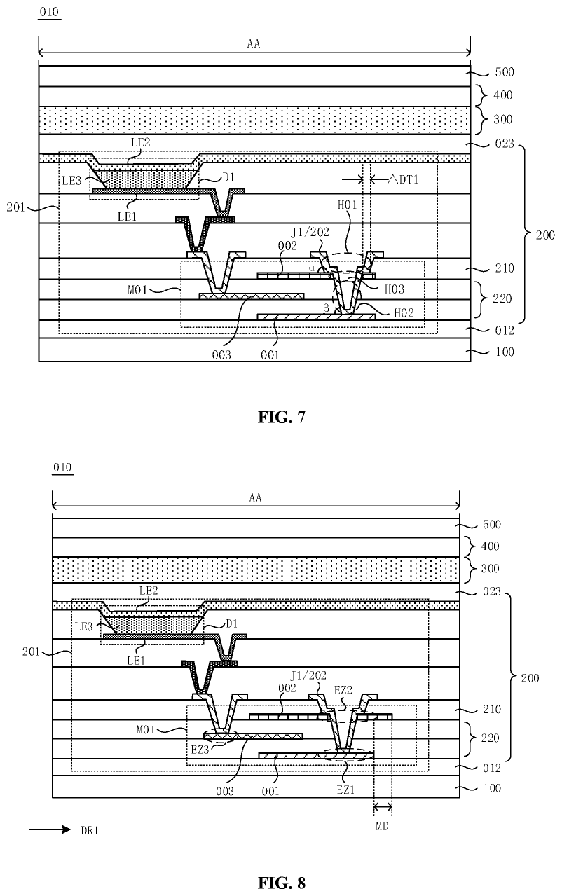

In an embodiment, FIG. 7 is a third schematic diagram of a film structure of a display panel according to an embodiment of the present application. Referring to FIG. 7, the circuit functional layer 200 further includes a first dielectric layer 210 between the second gate 002 and the first conductive structure 202, and a second dielectric layer 220 between the first gate 001 and the second gate 002. The first dielectric layer 210 includes a first etching hole H01, the second dielectric layer 220 includes a second etching hole H02, and the second gate 002 includes a third etching hole H03. Along the direction perpendicular to the plane where the substrate 100 is located, the first etching hole H01, the second etching hole H02 and the third etching hole H03 overlap. The first connection portion J1 is provided in all of the first etching hole H01, the second etching hole H02 and the third etching hole H03.

In an embodiment, the first connection portion J1 can connect the second gate 002 through the first etching hole H01, and the first connection portion J1 can also connect the first gate 001 through the first etching hole H01, the second etching hole H02 and the third etching hole H03. Along the direction perpendicular to the plane where the substrate 100 is located, the first etching hole H01, the second etching hole H02 and the third etching hole H03 overlap. The first etching hole H01, the second etching hole H02 and the third etching hole H03 can form a composite via hole penetrating through the first dielectric layer 210, the second gate 002 and the second dielectric layer 220. In this way, it is beneficial to reduce the number of via holes in the first dielectric layer 210. There is no need to additionally provide a via hole for connecting the first gate 001 in the first dielectric layer 210, which is beneficial to reduce the space occupied by the pixel circuit 201, thereby improving the performance of the display panel 010.

In an embodiment, the third etching hole H03 can be formed in a process of forming the second gate 002. When the surface of the first dielectric layer 210 is exposed and developed and the first dielectric layer 210 is etched to form the first etching hole H01, the second dielectric layer 220 between the second gate 002 and the first gate 001 can also be etched through the third etching hole H03 of the second gate 002 in the same process to form the second etching hole H02. The first etching hole H01 of the first dielectric layer 210 and the second etching hole H02 of the second dielectric layer 220 can be formed in the same process. On the one hand, it is beneficial to reduce the processes, and it is not necessary to form the first etching hole H01 and the second etching hole H02 in two separate processes, which is beneficial to improve the manufacturing efficiency and reduce the manufacturing cost. On the other hand, the process of forming the second etching hole H02 using the second gate 002 as a mask can reduce the precision requirement in the manufacturing process. It is not necessary to consider the alignment problem between the third etching hole H03 and the second etching hole H02 of the second dielectric layer 220, which is beneficial to reduce the manufacturing difficulty and production cost. If the first etching hole H01 and the second etching hole H02 are formed in two separate processes, the precision requirement in the manufacturing process needs to be improved to ensure the alignment between the third etching hole H03 and the second etching hole H02.

In an embodiment, continuing to refer to FIG. 7, a diameter of a side of the first etching hole H01 close to the substrate 100 is smaller than or equal to a diameter of a side of the first etching hole H01 away from the substrate 100.

Exemplarily, along the direction perpendicular to the plane where the substrate 100 is located, the closer to the substrate 100, the smaller the diameter of the first etching hole H01. In one embodiment, during forming the first connection portion J1, the first connection portion J1 can be effectively attached to the sidewall of the first etching hole H01, improving the reliability of the connection between the first connection portion J1 and the first gate 001 and the connection between the first connection portion J1 and the second gate 002.

On the basis of the above embodiment, continuing to refer to FIG. 7, an included angle α, which is between the sidewall of the first etching hole H01 and the plane where the substrate 100 is located and faces the first dielectric layer 210 is smaller than or equal to 90°, which can ensure that the first connection portion J1 on the sidewall of the first etching hole H01 is not disconnected to avoid an open circuit.

In another embodiment, continuing to refer to FIG. 7, a diameter of a side of the second etching hole H02 close to the substrate 100 is smaller than or equal to a diameter of a side of the second etching hole H02 away from the substrate 100.

Exemplarily, along the direction perpendicular to the plane where the substrate 100 is located, the closer to the substrate 100, the smaller the diameter of the second etching hole H02. In one embodiment, during forming the first connection portion J1, the first connection portion J1 can be effectively attached to the sidewall of the second etching hole H02, improving the reliability of the connection between the first connection portion J1 and the first gate 001.

On the basis of the above embodiment, continuing to refer to FIG. 7, the included angle β, which is between the sidewall of the second etching hole H02 and the plane where the substrate 100 is located and faces the second dielectric layer 220, is smaller than or equal to 90°, which can ensure that the first connection portion J1 on the sidewall of the second etching hole H02 will not be disconnected to avoid an open circuit.

In yet another embodiment, the minimum diameter of the third etching hole H03 is greater than or equal to 1.5 μm.

Exemplarily, along the direction perpendicular to the plane where the substrate 100 is located, the closer to the substrate 100, the smaller the diameter of the third etching hole H03. The minimum diameter of the third etching hole H03 is a diameter of a side of the third etching hole H03 closest to the substrate 100. The second gate 002 can serve as a mask layer or protective layer for forming the second etching hole H02 below. By limiting the minimum diameter of the third etching hole H03 to be greater than or equal to 1.5 μm, the maximum diameter of the second etching hole H02 located below the third etching hole H03 can be limited. When the process for forming the second etching hole H02 is determined, the sidewall slope of the second etching hole H02 and the thickness of the second dielectric layer 220 can be determined. By limiting the minimum diameter of the third etching hole H03 (i.e., the maximum diameter of the second etching hole H02) to be greater than or equal to 1.5 μm, the minimum diameter of the second etching hole H02 can be determined, avoiding that the minimum diameter of the second etching hole H02 is too small or the first gate 001 located below the second etching hole H02 is not exposed, which affects the reliability of the contact connection between the first connection portion J1 and the first gate 001.

In still another embodiment, a diameter of a side of the first etching hole H01 closest to the substrate 100 is greater than a diameter of a side of the third etching hole H03 farthest from the substrate 100.

The minimum aperture of the first etching hole H01 is greater than the maximum aperture of the third etching hole H03, and the first etching hole H01 can completely cover the third etching hole H03 and expose a part of the second gate 002. In this way, when the first connection portion J1 is formed in the first etching hole H01, the third etching hole H03 and the second etching hole H02, the first connection portion J1 can be formed on a part of the surface of the second gate 002 away from the substrate 100. Thus, the first connection portion J1 can in contact connection with both the sidewall of the second gate 002 (i.e., the sidewall of the third etching hole H03) and a part of the surface of the second gate 002 away from the substrate 100, which is beneficial to increase the contact area between the first connection portion J1 and the second gate 002, reduce the contact resistance, and increase the reliability of the connection between the first connection portion J1 and the second gate 002.

On the basis of the above embodiment, continuing to refer to FIG. 7, the distance between the edge of the first etching hole H01 closest to the substrate 100 and the edge of the third etching hole H03 away from the substrate 100 is ΔDT1, wherein ΔDT1 is greater than or equal to the thickness of the second gate 002, and smaller than or equal to 0.5 μm.

In an embodiment, the thickness of the second gate 002 is usually 0.3 μm. By setting ΔDT1 to be greater than or equal to the thickness of the second gate 002, the contact area between the first connection portion J1 and the surface of the second gate 002 away from the substrate 100 can be effectively increased, and the contact resistance can be reduced. In addition, ΔDT1≤0.5 μm is beneficial to reduce the area of the extension area of the second gate 002 and the aperture size of the first etching hole H01, thereby reducing the occupied space of the first transistor M01.

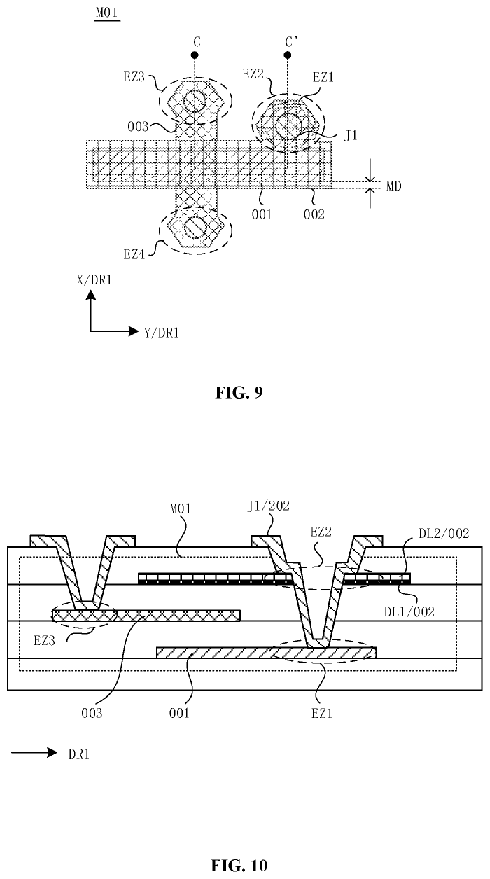

In an embodiment, FIG. 8 is a fourth schematic diagram of a film structure of a display panel according to an embodiment of the present application, and FIG. 9 is a second schematic top view of a first transistor according to an embodiment of the present application. The cross-sectional structure of the first transistor M01 along the dashed line C-C′ in FIG. 9 is shown in FIG. 8. Referring to FIG. 8 and FIG. 9, along the direction perpendicular to the plane where the substrate 100 is located, the first gate 001 and the second gate 002 overlap. A size of the first gate 001 in a first direction DR1 is different from a size of the second gate 002 in the first direction DR1. The first direction DR1 is parallel to the plane where the substrate 100 is located.

The first direction DR1 may intersect or be parallel to a direction of the length of the channel in the first active structure 003. An orientation of the first direction DR1 is not particularly limited in the embodiments of the present application. In one embodiment, the first direction DR1 may be a column direction (the second direction X) of the display panel 010. In another embodiment, the first direction DR1 may be a row direction (the third direction Y) of the display panel 010. In yet another implementation, the first direction DR1 may also be a direction intersecting both the column direction (the second direction X) and the row direction (the third direction Y).

In an embodiment, both the first gate 001 and the second gate 002 include metal materials. Due to reasons such as geometric stress concentration and mismatch of mechanical properties between materials, the inorganic dielectric layer at step edges of the first gate 001 and the second gate 002 is prone to cracks. Especially, when the display panel 010 is bumped or subjected to impact, the inorganic dielectric layer is prone to cracks, which may affect the electrical connection stability of the conductive structures in other film layers, increase the connection resistance, and cause reliability problems. This problem is particularly prominent in the dual-gate structure. Usually, two gates of the dual-gate structure are designed in the same size, and even the same mask is used for preparation. When the sizes and arrangement positions of the two gates are completely the same, the crack effect of the inorganic dielectric layer at the step slopes of the two gates will be superimposed in the longitudinal space, aggravating the unreliability caused by the cracks. In the embodiments of the present application, by setting the sizes of the first gate 001 and the second gate 002 of the first transistor M01 in the first direction DR1 to be different, the unreliability caused by the crack effect at the step slope edges of the first gate 001 and the second gate 002 can be improved, avoiding that the crack effect at the step slope edges of the first gate 001 and the second gate 002 is superimposed in the longitudinal space, causing serious consequences and affecting the performance of the display panel 010.

In an embodiment, the orthographic projection of the first gate 001 on the plane where the substrate 100 is located is a first projection, and the orthographic projection of the second gate 002 on the plane where the substrate 100 is located is a second projection. In one first transistor M01, the minimum distance MD between the edge of the first projection and the edge of the second projection is greater than or equal to 0.5 μm. By limiting the minimum distance MD between the edge of the first projection and the edge of the second projection to be greater than or equal to 0.5 μm, the step slope edges of the first gate 001 and the second gate 002 can be arranged in a staggered manner in the longitudinal space, effectively improving the unreliability caused by the crack at the step slope edges of the first gate 001 and the second gate 002, and avoiding that the step slope edges of the first gate 001 and the second gate 002 are close to each other in the longitudinal space. The step slope edges close to each other may cause the crack effect of the first gate 001 and the second gate 002 to be superimposed in the longitudinal space and increase the unreliability.

In an embodiment, continuing to refer to FIG. 8 and FIG. 9, the size of the second gate 002 in the first direction DR1 is greater than the size of the first gate 001 in the first direction DR1.

In an embodiment, a vertical projection of the second gate 002 on the plane where the substrate 100 is located can cover a vertical projection of the first gate 001 on the plane where the substrate 100 is located. A vertical projection of the second extension area EZ2 on the plane where the substrate 100 is located can also cover a vertical projection of the first extension area EZ1 on the plane where the substrate 100 is located. By increasing the size of the second gate 002 located above the first gate 001, it is beneficial to reduce the number of metal step slopes directly exposed to the light-emitting layer, the encapsulation layer and the touch layer, thereby reducing the influence of the crack effect of the inorganic dielectric layer on the film layers such as the electrode layer, the light-emitting layer, the encapsulation layer and the touch layer.

The crack effect of the inorganic dielectric layer at the step slope edge of the first gate 001 located below the second gate 002 may affect the second gate 002 located above the first gate 001, but this influence is small. On the one hand, the position of the step slope edge of the first gate 001 located below the second gate 002 is usually near the edge of the second gate 002 in the longitudinal space. Even if the crack effect of the inorganic dielectric layer at the step slope edge of the first gate 001 affects the electrical connection of the second gate 002, it only affects the structural integrity near the edge of the second gate 002, and does not affect the core (functioning, actually used for electrical connection) area of the second gate 002. Thus, this crack effect will not affect the performance of the first transistor M01. On the other hand, the first gate 001 and second gate 002 overlapping in the direction perpendicular to the plane where the substrate 100 is located usually has a short distance in the longitudinal space. Even if there is a crack in the inorganic dielectric layer between the first gate 001 and second gate 002, this crack is usually not too large, and the adverse effect caused is much smaller than the influence on the film layers such as the electrode layer, the light-emitting layer, the encapsulation layer and the touch layer. Therefore, by setting the size of the second gate 002 in the first direction DR1 to be greater than the size of the first gate 001 in the first direction DR1, the problem of poor reliability caused by the crack effect of the first gate 001 and the second gate 002 of the first transistor M01 can be effectively improved.

In another embodiment, FIG. 10 is a schematic diagram of a film structure of a first transistor according to an embodiment of the present application. Referring to FIG. 10, the second gate 002 includes a first deposition layer DL1 and a second deposition layer DL2. The first deposition layer DL1 is located on a side of the second deposition layer DL2 close to the substrate 100. Young's modulus of the first deposition layer DL1 is smaller than Young's modulus of the second deposition layer DL2.

Young's modulus is a physical quantity that indicates an ability of a material to resist tensile or compressive deformation within the elastic range. The unit of Young's modulus is Pascal (Pa), megapascal (MPa) or gigapascal (GPa). Materials with a small Young's modulus usually have better plasticity, are easier to be stretched and are not easy to break. By providing the first deposition layer DL1 with a small Young's modulus on the side of the second gate 002 close to the substrate 100, it is beneficial to reduce the influence of the crack effect at the step slope edge of the first gate 001 on the second gate 002. In addition, only providing the first deposition layer DL1 in the second gate 002, which is located above the first gate 001, is beneficial to reduce the manufacturing processes and reduce the manufacturing cost.

In an embodiment, the first gate 001 and the second deposition layer DL2 may include molybdenum (Mo) metal. The first deposition layer DL1 may include titanium (Ti) material.

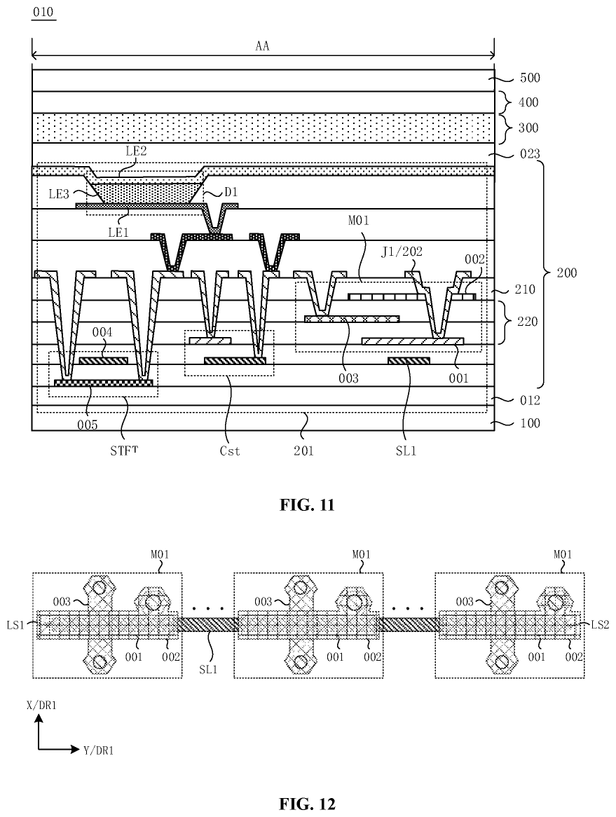

In an embodiment, FIG. 11 is a fifth schematic diagram of a film structure of a display panel according to an embodiment of the present application, and FIG. 12 is a third schematic top view of a first transistor according to an embodiment of the present application. Referring to FIG. 11 and FIG. 12, the circuit functional layer 200 further includes a first signal line SL1 on a side of the first transistor M01 close to the substrate 100. The first signal line SL1 is electrically connected to multiple pixel circuits 201 (not shown in FIG. 11 and FIG. 12). Along the direction perpendicular to the plane where the substrate 100 is located, the first signal line SL1 overlaps both the first gates 001 and the second gates 002 of multiple first transistors M01.

The first signal line SL1 is used to transmit an electrical signal and provide the electrical signal to the pixel circuits 201. In one embodiment, the first signal line SL1 extends along the row direction (the third direction Y). The first signal line SL1 can be electrically connected to multiple pixel circuits 201 in one row. Exemplarily, the first signal line SL1 is a scan line for transmitting signals, such as, a write control signal S2P, a compensation control signal S2N, an initialization control signal S1N, and a reset control signal S1P. In another embodiment, the first signal line SL1 extends along the column direction (the second direction X), and the first signal line SL1 can be electrically connected to multiple pixel circuits 201 in one column. Exemplarily, the first signal line SL1 is used to transmit signals, such as, a write data signal Data, an initialization signal VREF1, and a reset signal VREF2.

In an embodiment, taking a case where the first signal line SL1 is electrically connected to the gates of other transistors in the pixel circuit 201 except the first transistor M01 and the first signal line SL1 can provide a gate driving signal to the gates of other transistors as an example, referring to FIG. 11, at least part of the switching transistors STFT in the pixel circuit 201 are not set as the first transistor M01. This part of switching transistors STFT include a switching gate 004 and a switching active structure 005. The switching gate 004 and the switching active structure 005 can both be located on a side of the first transistor M01 close to the substrate 100. In one embodiment, the first signal line SL1 can be arranged in the same layer as the switching gate 004. On this basis, the switching gate 004 can also reuse the first signal line SL1 (not shown in FIG. 11).

Continuing to refer to FIG. 11 and FIG. 12, the first signal line SL1 is located on the side of the first transistor M01 close to the substrate 100, which can reduce the influence of the crack effect of the first gate 001 and the second gate 002 of the first transistor M01, and avoid that the crack effect of the first gate 001 and/or the second gate 002 causes the breakage of the first signal line SL1 and affects the electrical connection of the first signal line SL1. In addition, along the direction perpendicular to the plane where the substrate 100 is located, the first signal line SL1 overlaps both the first gates 001 and the second gates 002 of multiple first transistors M01, which can save the space of the circuit functional layer 200, increase the light transmittance, and is also beneficial to the high resolution and thinning of the display panel 010. In one embodiment, the size of the first signal line SL1 in the first direction DR1 is different from the size of the second gate 002 in the first direction DR1, and/or, the size of the first signal line SL1 in the first direction DR1 is different from the size of the first gate 001 in the first direction DR1, to avoid that the crack effect at the step slope edge of the first signal line SL1 is superimposed in the longitudinal space, causing serious consequences and affecting the performance of the display panel 010.

In an embodiment, continuing to refer to FIG. 12, a size of the first signal line SL1 in the second direction X is smaller than a size of the second gate 002 in the second direction X. The second direction X is parallel to the plane where the substrate 100 is located, and intersects an extension direction of the first signal line SL1.

In an embodiment, the first signal line SL1 extends along the row direction, and the second direction X may be the column direction. The first signal line SL1 can be electrically connected to multiple pixel circuits 201 in the same row. Along the extension direction of the first signal line SL1, the size of the first signal line SL1 is usually larger than the size of the second gate 002. By setting the size of the first signal line SL1 in the second direction X to be smaller than the size of the second gate 002 in the second direction X, it is beneficial to reduce the number of metal step slopes directly exposed to the light-emitting layer, the encapsulation layer and the touch layer, thereby reducing the influence of the crack effect of the inorganic dielectric layer on the film layers such as the electrode layer, the light-emitting layer, the encapsulation layer and the touch layer.

In other implementations, the first signal line may also extend along the column direction, and the second direction may be the row direction.

In another embodiment, continuing to refer to FIG. 12, a size of the first signal line SL1 in the second direction X is smaller than a size of the first gate 001 in the second direction X. The second direction X is parallel to the plane where the substrate 100 is located, and intersects the extension direction of the first signal line SL1. This arrangement is also beneficial to reduce the number of metal step slopes directly exposed to the light-emitting layer, the encapsulation layer and the touch layer, thereby reducing the influence of the crack effect of the inorganic dielectric layer on the film layers such as the electrode layer, the light-emitting layer, the encapsulation layer and the touch layer.

In an embodiment, along the second direction X, the size of the first signal line SL1 is smaller than the size of the first gate 001, and the size of the first gate 001 is smaller than the size of the second gate 002, which is beneficial to reduce the number of metal step slopes directly exposed to the second gate 002, and improve the reliability of the second gate 002.

In yet another embodiment, the first signal line SL1 includes a first edge LS1, and a second edge LS2 opposite to the first edge LS1 along the third direction Y. The third direction Y is parallel to the extension direction of the first signal line SL1. The orthographic projection of the first gate 001 on the plane where the substrate 100 is located is a first projection, and the orthographic projection of the second gate 002 on the plane where the substrate 100 is located is a second projection. The orthographic projections of the first edge LS1 and the second edge LS2 on the plane where the substrate 100 is located are covered by the first projection, and the minimum distance between the first edge LS1 and the edge of the first projection and the minimum distance between the second edge LS2 and the edge of the first projection are both greater than zero; and/or, the orthographic projections of the first edge LS1 and the second edge LS2 on the plane where the substrate 100 is located are covered by the second projection, and the minimum distance between the first edge LS1 and the edge of the second projection and the minimum distance between the second edge LS2 and the edge of the second projection are both greater than zero.

In an embodiment, the first edge LS1 and the second edge LS2 both overlap the first gate 001 along the direction perpendicular to the plane where the substrate 100 is located, and along the direction perpendicular to the plane where the substrate 100 is located, the distance between the first edge LS1 and the edge of the first gate 001 and the distance between the second edge LS2 and the edge of the first gate 001 are both greater than zero; and/or, the first edge LS1 and the second edge LS2 both overlap the second gate 002 along the direction perpendicular to the plane where the substrate 100 is located, and along the direction perpendicular to the plane where the substrate 100 is located, the distance between the first edge LS1 and the edge of the second gate 002 and the distance between the second edge LS2 and the edge of the second gate 002 are both greater than zero. In the longitudinal space (the direction perpendicular to the plane where the substrate 100 is located), the first edge LS1 and the second edge LS2 are retracted relative to the edge of the first gate 001 towards the center area of the first signal line SL1 and/or the first gate 001; and/or, in the longitudinal space (the direction perpendicular to the plane where the substrate 100 is located), the first edge LS1 and the second edge LS2 are retracted relative to the edge of the second gate 002 towards the center area of the first signal line SL1 and/or the second gate 002. This arrangement is beneficial to reduce the number of metal step slopes directly exposed to the side away from the substrate 100, reduce the influence of the crack effect of the inorganic dielectric layer, and improve the reliability of the display panel 010.

In an embodiment, the first signal line SL1 can run through the display area AA in the third direction Y (the row direction) and connect all the pixel circuits 201 in the same row. Although the size of the first signal line SL1 is larger than the size of the first gate 001 along the third direction Y (the row direction), the first edge LS1 and the second edge LS2 of the first signal line SL1 are retracted relative to the first gates 001 of two first transistors M01 located at the outermost sides among all the pixel circuits 201 in the same row; and/or the first edge LS1 and the second edge LS2 of the first signal line SL1 are retracted relative to two second gates 002 of the first transistors M01 located at the outermost sides among all the pixel circuits 201 in the same row. This arrangement can avoid the crack effect of the first edge LS1 and/or the second edge LS2 affecting the film structure on the side of the first transistor M01 away from the substrate 100. The crack effect of the first edge LS1 and the second edge LS2 has a small influence on the first gate 001 and the second gate 002 of the first transistor M01. Even if the crack effect affects the first gate 001 and the second gate 002, it only affects the structural integrity near the edges of the first gate 001 and the second gate 002, which does not affect the core areas of the first gate 001 and the second gate 002.

In other implementations, the second signal line can run through the display area AA in the sixth direction (the column direction) and connect all the pixel circuits 201 in the same column.

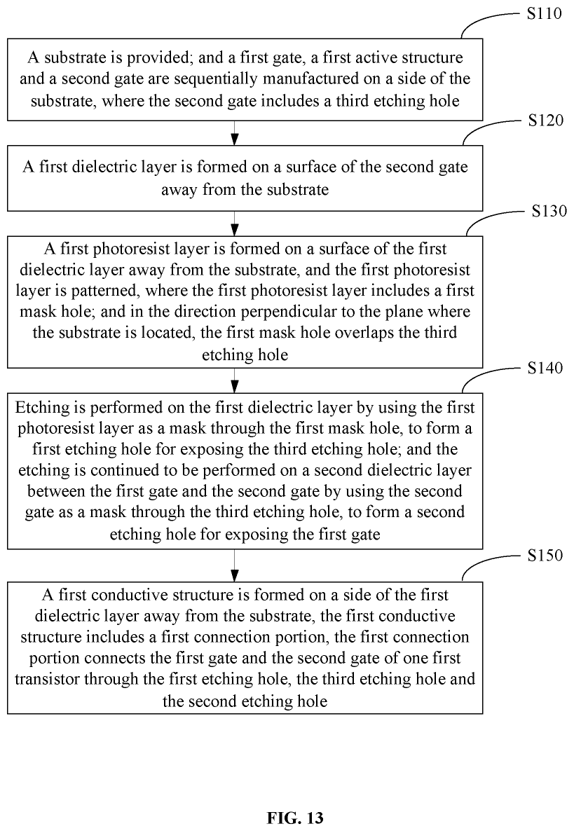

Based on the same inventive concept, a method for manufacturing a display panel is further provided according to an embodiment of the present application, which is used to manufacture the display panel shown in FIG. 2, FIG. 5, FIG. 7, FIG. 8, and FIG. 11. FIG. 13 is a first flowchart of a method for manufacturing a display panel according to an embodiment of the present application. Referring to FIG. 13, the method includes S110 to S150.

In S110, a substrate is provided; and a first gate, a first active structure and a second gate are sequentially manufactured on a side of the substrate. The second gate includes a third etching hole.

Exemplarily, referring to FIG. 2, FIG. 5, FIG. 7, FIG. 8 and FIG. 11, before the first gate 001, the first active structure 003 and the second gate 002 are manufactured on the side of the substrate 100, structures such as a protective layer 012, a photosensitive layer 260, a switching active structure 005, a switching gate 004, a first signal line SL1, and dielectric layers adjacent to these structures can be selectively formed. Then, the first gate 001 is formed first, then the first active structure 003 is formed, and finally the second gate 002 is formed. In one embodiment, the third etching hole H03 can be formed in a process of forming the second gate 002.

In S120, a first dielectric layer is formed on a surface of the second gate away from the substrate.

In an embodiment, after the second gate 002 is formed, an entire layer of the first dielectric layer 210 can be formed on the surface of the second gate 002 away from the substrate 100. The first dielectric layer 210 can fill and cover the third etching hole H03.

In S130, a first photoresist layer is formed on a surface of the first dielectric layer away from the substrate, and the first photoresist layer is patterned. The first photoresist layer includes a first mask hole. In the direction perpendicular to the plane where the substrate is located, the first mask hole overlaps the third etching hole.

In an embodiment, a photolithography process can be used to pattern the entire layer of the first dielectric layer 210. In one embodiment, the minimum diameter of the first mask hole is larger than the maximum diameter of the third etching hole H03.

In S140, etching is performed on the first dielectric layer by using the first photoresist layer as a mask through the first mask hole, to form a first etching hole for exposing the third etching hole; and the etching is continued to be performed on a second dielectric layer between the first gate and the second gate by using the second gate as a mask through the third etching hole, to form a second etching hole for exposing the first gate.

In an embodiment, the first etching hole H01 in the first dielectric layer 210 is formed in an etching process. After the first etching hole H01 is formed by etching, the etching can be continued. The second dielectric layer 220 between the first gate 001 and the second gate 002 continues to be etched by using the second gate 002 as a mask, to form the second etching hole H02 exposing the first gate 001. In one embodiment, the first etching hole H01 and the second etching hole H02 can be formed by one etching process.

In S150, a first conductive structure is formed on a side of the first dielectric layer away from the substrate. The first conductive structure includes a first connection portion. The first connection portion connects the first gate and the second gate of one first transistor through the first etching hole, the third etching hole and the second etching hole.

In an embodiment, after the first etching hole H01 and the second etching hole H02 are formed, an entire layer of a conductive layer can be formed on the surface of the first dielectric layer 210 away from the substrate 100. The conductive layer can be formed on the surface of the first dielectric layer 210 away from the substrate 100, and the conductive layer can also be formed on the sidewalls of the first etching hole H01, the third etching hole H03 and the second etching hole H02, and the exposed surface of the first gate 001 away from the substrate 100. Then, the conductive layer is patterned to obtain the first conductive structure 202 that connects both the first gate 001 and the second gate 002.

In the embodiments of the present application, the first etching hole of the first dielectric layer and the second etching hole of the second dielectric layer can be formed in the same process, which is beneficial to reduce the processes. It is not necessary to form the first etching hole and the second etching hole in two separate processes, which is beneficial to improve the manufacturing efficiency and reduce the manufacturing cost. In addition, the second etching hole is formed using the second gate as a mask, which can reduce the precision requirement in the manufacturing process. It is not necessary to consider the alignment problem between the third etching hole and the second etching hole of the second dielectric layer, which is beneficial to reduce the manufacturing difficulty and production cost.

The method for manufacturing the display panel according to the embodiments of the present application is used to manufacture the display panel according to the above embodiments of the present application, and has corresponding technical features and beneficial effects of the display panel. For the content not described in detail in the embodiments of the method for manufacturing the display panel, reference can be made to the above description of the display panel, which will not be repeated here. Similarly, the display panel of the embodiments of the present application also has the functional modules and beneficial effects for executing the method for manufacturing the display panel according to the embodiments of the present application. For the content not described in detail in the embodiments of the display panel, reference can be made to the above description of the method for manufacturing a display panel, and will not be repeated here.

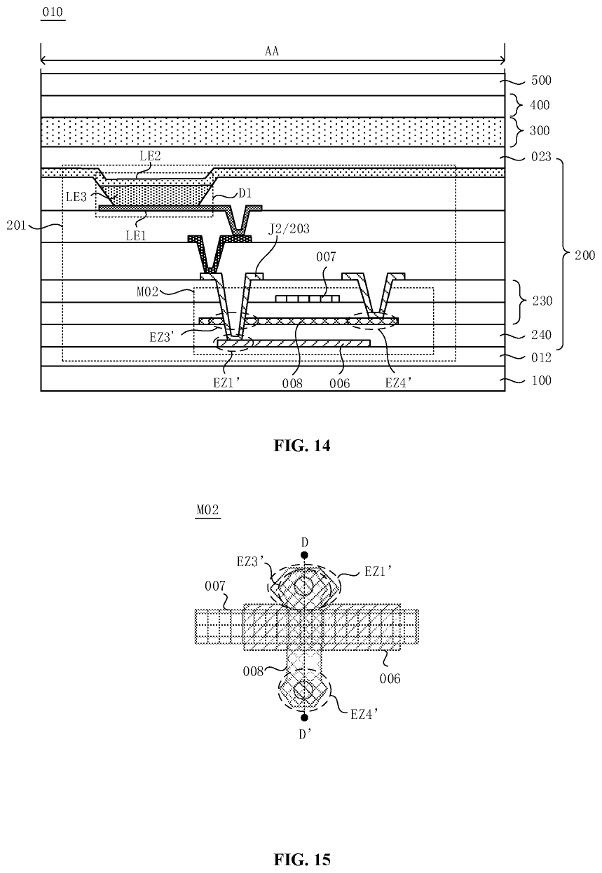

Based on the same inventive concept, a display panel is further provided according to another embodiment of the present application. FIG. 14 is a sixth schematic diagram of a film structure of a display panel according to an embodiment of the present application. FIG. 14 may be a schematic cross-sectional view of the display panel 010 along the dashed line A-A′ in FIG. 1. Referring to FIG. 1 and FIG. 14, the display panel 010 includes a substrate 100, and a circuit functional layer 200 on a side of the substrate 100. The circuit functional layer 200 includes multiple pixel circuits 201 in a display area AA. At least part of the pixel circuits 201 include a second transistor M02 and a light-emitting element D1. The second transistor M02 includes a third gate 006, a fourth gate 007 and a second active structure 008. The third gate 006 is located on a side of the second active structure 008 close to the substrate 100, and the fourth gate 007 is located on a side of the second active structure 008 away from the substrate 100.

FIG. 15 is a first schematic top view of a second transistor according to an embodiment of the present application. The cross-sectional structure of the second transistor M02 along the dashed line D-D′ in FIG. 15 is shown in FIG. 14. Referring to FIG. 14 and FIG. 15, the circuit functional layer 200 further includes a second conductive structure 203 on a side of the fourth gate 007 away from the substrate 100. The second conductive structure 203 includes a second connection portion J2. Along the direction perpendicular to the plane where the substrate 100 is located, the second connection portion J2 overlaps an overlapping area of the third gate 006 and the second active structure 008 of one second transistor M02, and the second connection portion J2 connects the third gate 006 and the second active structure 008 of the one second transistor M02.

The pixel circuit 201 in the display area AA includes, but is not limited to, a pixel circuit, such as 2T1C, 6T2C, 7T1C, 8T1C. The second transistor M02 may be any transistor in the pixel circuit 201. The second transistor M02 may be an LTPS-TFT or IGZO-TFT. The second transistor M02 may be a P-type transistor or an N-type transistor. The arrangement position, the material of the active structure and the channel type of the second transistor M02 in the pixel circuit 201 will not be limited in the embodiments of the present application.

In an embodiment, the second transistor M02 is a dual-gate transistor. The third gate 006 is a newly added gate of the second transistor M02, by which the second transistor M02 may have a better channel charge control capability. The fourth gate 007 is a driving gate of the second transistor M02. The on-off state of the second transistor M02 can be controlled by the potential of the fourth gate 007. The second conductive structure 203 can be used to transmit a source signal or a drain signal, and provide the signal to the source area or the drain area of the second active structure 008. The second connection portion J2 of the second conductive structure 203 can connect the third extension area EZ3′ of the second active structure 008, to realize reliable electrical connection between the second conductive structure 203 and the source area or the drain area of the second active structure 008.

Along the direction perpendicular to the plane where the substrate 100 is located, the second connection portion J2 of the second conductive structure 203 also connects the first extension area EZ1′ of the third gate 006, to provide the gate driving signal to the third gate 006 by the second conductive structure 203 to control the potential of the third gate 006. In addition, the third gate 006 and the source area or the drain area of the second active structure 008 can be electrically connected through the second connection portion J2, and the third gate 006 has the same potential as the source area or the drain area of the second active structure 008, which is beneficial to suppress the threshold voltage shift of the second transistor M02, improve working stability of the second transistor M02, extend service life of the second transistor M02, and thus improve the display effect and reliability of the display panel 010. In addition, along the direction perpendicular to the plane where the substrate 100 is located, the second connection portion J2 overlaps the overlapping area of the second active structure 008 and the third gate 006 of the same second transistor M02. That is, the second connection portion J2 overlaps both the third extension area EZ3′ of the second active structure 008 and the first extension area EZ1′ of the third gate 006. The newly added extension area (the first extension area EZ1′) overlaps an original extension area (the third extension area EZ3′). There is no need to additionally provide a space for overlapping the newly added gate (the third gate 006), which is beneficial to reduce the influence on the arrangement of the pixel circuit 201 in the display panel 010 while improving the performance of the second transistor M02, thereby improving the resolution and thinning, and avoiding increasing the space occupied by the extension area of the second transistor M02 in the direction perpendicular to the plane where the substrate 100 is located. The increased space may affect the arrangement of the pixel circuit 201 in the display panel 010 and is not conducive to improving the performance of the display panel.

The fourth gate 007 includes a second extension area (not shown in FIG. 14 and FIG. 15), and the second transistor M02 also includes four extension areas, i.e., the first extension area EZ1′, the second extension area, the third extension area EZ3′ and the fourth extension area EZ4′. The vertical projections of the first extension area EZ1′ and the third extension area EZ3′ on the plane where the substrate 100 is located overlap, and the vertical projection of the second transistor M02 on the plane where the substrate 100 is located only occupies the space of three extension areas on the plane where the substrate 100 is located. This arrangement can also effectively reduce the space occupation while realizing the performance improvement of the second transistor M02, and improve the performance of the display panel 010.

In an embodiment, in a process of manufacturing the second transistor M02 in the circuit functional layer 200, the third gate 006 can be formed first, then the second active structure 008 is formed, and finally the fourth gate 007 is formed. Along the direction perpendicular to the plane where the substrate 100 is located, a partial area of the overlapping area of the second active structure 008 and the third gate 006 does not overlap the fourth gate 007. In the partial area, the third extension area EZ3′ and the first extension area EZ1′ overlap, and both of the third extension area EZ3′ and the first extension area EZ1′ do not overlap the fourth gate 007. This partial area can overlap the second connection portion J2 of the second conductive structure 203. That is, the third extension area EZ3′ and the first extension area EZ1′ both overlap the first connection portion J1.

After the second transistor M02 is manufactured, i.e., after the fourth gate 007 is formed, the second conductive structure 203 is formed. The second connection portion J2 of the second conductive structure 203 can overlap both the third extension area EZ3′ of the second active structure 008 and the first extension area EZ1′ of the third gate 006.

After the second conductive structure 203 is formed, structures, such as, the light-emitting element D1, the encapsulation layer 023, the touch functional layer 300, the optical functional layer 400, and the cover plate 500, can be manufactured on a side of the second conductive structure 203 away from the substrate 100, which will not be described one by one in the embodiments of the present application.

Each of the pixel circuits 201 located in the display area AA in the circuit functional layer 200 may include the second transistor M02. In one embodiment, only a part of the pixel circuits 201 may include the second transistor M02. That is, the pixel circuits 201 in a part of the display area AA in the circuit functional layer 200 do not include the second transistor M02, and the pixel circuits 201 located in a part of the display area AA in the circuit functional layer 200 include the second transistor M02. In one embodiment, the transistors in the pixel circuit 201 provided with the second transistor M02 in the circuit functional layer 200 may all be the second transistor M02. In other implementations, in the circuit functional layer 200, a part of the transistors in the pixel circuit 201 provided with the second transistor M02 may be the second transistor M02. That is, in the circuit functional layer 200, the pixel circuit 201 provided with the second transistor M02 may further include other transistors different from the second transistor M02 in one or more of the film arrangement position, structure, material and connection method, such as the first transistor M01 provided above.

Along the direction perpendicular to the plane where the substrate 100 is located, the first extension area EZ1′ of the third gate 006 and the third extension area EZ3′ of the second active structure 008 of the second transistor M02 overlap, and the first extension area EZ1′ and the third extension area EZ3′ both connect the second connection portion J2 of the second conductive structure 203. Regardless of which transistors in the display panel 010 are the second transistor M02, the second conductive structure 203 is provided directly above a side of the second transistor M02 away from the substrate 100, i.e., the overlapping area along the direction perpendicular to the plane where the substrate 100 is located. Along the direction perpendicular to the plane where the substrate 100 is located, the second connection portion J2 of the second conductive structure 203 overlaps both the first extension area EZ1′ of the third gate 006 and the third extension area EZ3′ of the second active structure 008 of the same second transistor M02, which can realize the improvement of the transistor performance, and effectively reduce the space occupation and improve the performance of the display panel.

In the embodiments of the present application, the second transistor with a dual-gate structure is arranged in the pixel circuit. In the second transistor, the second connection portion of the second conductive structure connects the third gate and the second active structure of the same second transistor, to electrically connect the third gate of this second transistor and the source area or the drain area of the second active structure of this second transistor, which is beneficial to suppress the threshold voltage shift of the second transistor, improve its working stability, extend its service life, and thus improve the display effect and reliability of the display panel 010. In addition, along the direction perpendicular to the plane where the substrate is located, the second connection portion of the second conductive structure overlaps the overlapping area of the third gate and the second active structure of the same second transistor, to overlap the first extension area of the third gate and the third extension area of the second active structure along the direction perpendicular to the plane where the substrate is located, which can reduce the space occupied by the extension area of the second transistor in the direction perpendicular to the plane where the substrate is located while improving the performance of the second transistor, thereby reducing the space occupied by the pixel circuit. This arrangement is beneficial to improve the resolution and thinning of the display panel. In addition, when the display panel is a transparent display panel or a partially transparent display panel, it is also beneficial to improve the light transmittance of the display panel.

In one embodiment, the display panel 010 may be provided with both the first transistor M01 and the second transistor M02. On this basis, one pixel circuit 201 may be provided with both the first transistor M01 and the second transistor M02. In another embodiment, the display panel 010 may be provided with only the second transistor M02. On this basis, the pixel circuit 201 may be provided with only the second transistor M02. Similarly, the display panel 010 may also be provided with only the first transistor M01. On this basis, the pixel circuit 201 may be provided with only the first transistor M01.

The filling patterns and reference numerals in the figures can both be used to distinguish different structures. Although the third gate 006 in FIG. 14 has the same filling pattern as the first gate 001 in FIG. 2, the third gate 006 in FIG. 14 and the first gate 001 in FIG. 2 have different reference numerals, which thus may be different structures. Similarly, the fourth gate 007 in FIG. 14 and the second gate 002 in FIG. 2 may have different structures, the second active structure 008 in FIG. 14 and the first active structure 003 in FIG. 2 may have different structures, and the second conductive structure 203 in FIG. 14 and the first conductive structure 202 in FIG. 2 may have different structures.

It should also be noted that the filling patterns in the figures are not used to distinguish the film layer material, that is, the same filling pattern may be the same film layer material, or different film layer materials. Although the third gate 006 in FIG. 14 has the same filling pattern as the first gate 001 in FIG. 2, film layer materials of the third gate 006 in FIG. 14 and the first gate 001 in FIG. 2 are the same or different. The relationship (such as the film layer relationship, the position relationship, etc.) between the third gate 006 in FIG. 14 and the first gate 001 in FIG. 2 is not limited in the embodiments of the present application. In one embodiment, the third gate 006 and the first gate 001 may be made of the same film layer material. On this basis, the third gate 006 and the first gate 001 can be arranged in the same layer and formed in the same process. In another embodiment, the third gate 006 and the first gate 001 may also be made of different film layer materials, and the third gate 006 and the first gate 001 can be arranged in different layers and formed in different processes.

Similarly, the film layer materials of the fourth gate 007 in FIG. 14 and the second gate 002 in FIG. 2 may be the same or different. The relationship (such as the film layer relationship, the position relationship, etc.) between the fourth gate 007 in FIG. 14 and the second gate 002 in FIG. 2 is not limited in the embodiments of the present application. The film layer materials of the second active structure 008 in FIG. 14 and the first active structure 003 in FIG. 2 may be the same or different. The relationship (such as the film layer relationship, the position relationship, etc.) between the second active structure 008 in FIG. 14 and the first active structure 003 in FIG. 2 is not limited in the embodiments of the present application. The film layer materials of the second conductive structure 203 in FIG. 14 and the first conductive structure 202 in FIG. 2 may be the same or different. The relationship (such as the film layer relationship, the position relationship, etc.) between the second conductive structure 203 in FIG. 14 and the first conductive structure 202 in FIG. 2 is not limited in the embodiments of the present application.

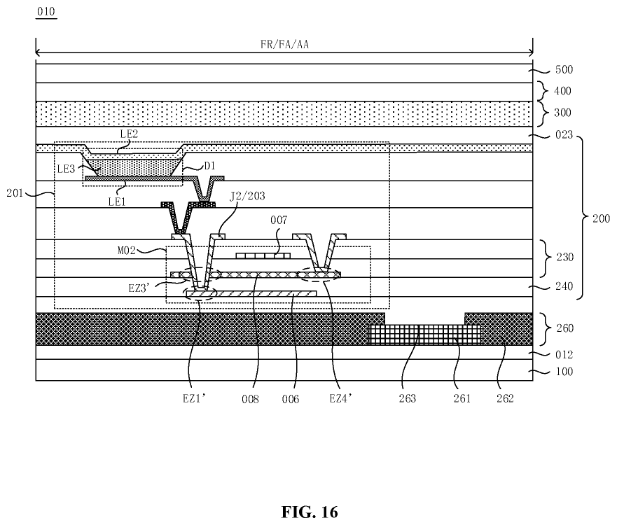

In an embodiment, FIG. 16 is a seventh schematic diagram of a film structure of a display panel according to an embodiment of the present application. Referring to FIG. 4 and FIG. 16, the display area AA includes a functional device arrangement area FA and a main display area MA at least partially surrounding the functional device arrangement area FA. The functional device arrangement area FA includes a pixel circuit 201 and a functional device 261 on a side of the pixel circuit 201 close to the substrate 100. The circuit functional layer 200 in the functional device arrangement area FA includes the second transistors M02 and the second conductive structures 203. One second conductive structure of the second conductive structures 203 connects the third gate 006 and the second active structure 008 of the same second transistor M02.

In an embodiment, taking the functional device arrangement area FA as the fingerprint recognition area FR as an example, referring to FIG. 16, by providing the second transistor M02 and the second conductive structure 203 connecting the third gate 006 and the second active structure 008 of this second transistor M02 in the circuit functional layer 200 in the functional device arrangement area FA, the space occupied by the pixel circuit 201 located in the functional device arrangement area FA can be reduced, the light transmittance of a side of the photosensitive layer 260 away from the substrate in the functional device arrangement area FA can be increased, which is beneficial to improve the sensitivity and accuracy of fingerprint recognition.

In other implementations, the circuit functional layer located in the main display area may also be provided with the second transistor and the second conductive structure connecting the third gate and the second active structure of this second transistor (not shown in FIG. 16).

In another embodiment, the second transistor M02 includes a driving transistor M3 and/or a switching transistor STFT. The driving transistor M3 is used to selectively provide a driving signal to the light-emitting element D1. The switching transistor STFT is used to selectively provide an electrical signal to the driving transistor M3 and/or the light-emitting element D1. On this basis, if the pixel circuit 201 further includes the first transistor M01, the first transistor M01 may include any other transistor except the second transistor M02. That is, the first transistor M01 and the second transistor M02 do not include the same transistor.

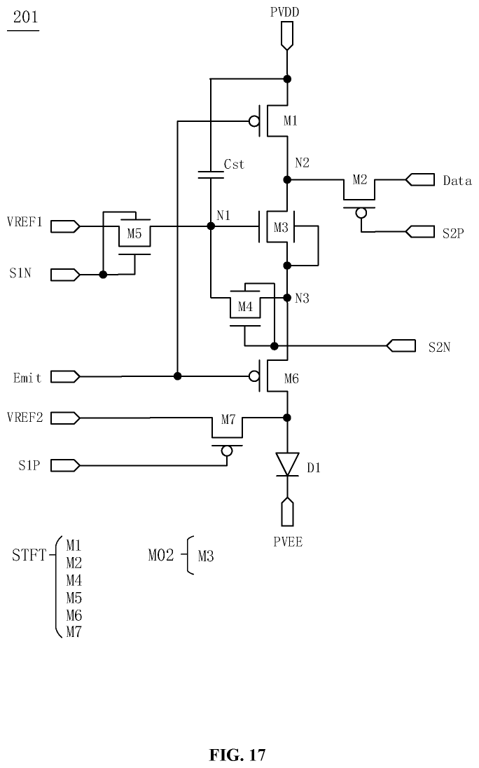

In an embodiment, FIG. 17 is a second schematic diagram of a circuit structure of a pixel circuit according to an embodiment of the present application. Referring to FIG. 17, the pixel circuit 201 is a 7T1C pixel circuit. The pixel circuit 201 may include a first light-emitting control transistor M1, a write transistor M2, a driving transistor M3, a compensation transistor M4, an initialization transistor M5, a second light-emitting control transistor M6, a reset transistor M7 and a storage capacitor Cst. The switching transistor STFT includes the first light-emitting control transistor M1, the write transistor M2, the compensation transistor M4, the initialization transistor M5, the second light-emitting control transistor M6 and the reset transistor M7. The driving transistor M3 and/or the switching transistor STFT in the pixel circuit 201 can be set as the second transistor M02 which is a dual-gate transistor. Along the direction perpendicular to the substrate 100, the first extension area EZ1′ of the third gate 006 and the third extension area EZ3′ of the second active structure 008 overlap, both of which connect the second connection portion J2 of the second conductive structure 203. In one embodiment, the driving transistor M3, the compensation transistor M4 and the initialization transistor M5 in at least part of the pixel circuits 201 are the second transistor M02. In another embodiment, all transistors in at least part of the pixel circuits 201 are set as the second transistor M02. In yet another implementation, the driving transistor M3 in at least part of the pixel circuits 201 is the second transistor M02.

FIG. 17 only exemplarily shows a circuit structure of the pixel circuit 201, but is not limited thereto. It is sufficient as long as at least one of the driving transistor M3 and the switching transistor STFT in the pixel circuit 201 is the second transistor M02, and the third gate 006 of the second transistor M02 and the second active structure 008 of the second transistor M02 both overlap the second connection portion J2 of the second conductive structure 203.

In yet another embodiment, the second active structure 008 of the second transistor M02 includes a metal oxide material. On this basis, if the pixel circuit 201 further includes the first transistor M01, the first active structure 003 of the first transistor M01 also includes a metal oxide material, and the second active structure 008 can be arranged in the same layer as the first active structure 003. In addition, the third gate 006 can be arranged in the same layer as the first gate 001, and/or the fourth gate 007 can be arranged in the same layer as the second gate 002.

On the basis of the above embodiment, the second active structure 008 of the second transistor M02 is of a linear design. In this way, it is beneficial to reduce the channel width-to-length ratio and further reduce the space occupied by the second transistor M02. When the second active structure 008 includes the metal oxide material, the second active structure 008 has good uniformity, and the second active structure 008 has high mobility and low leakage current. It is not necessary to set a long channel width-to-length ratio to meet the use requirements.

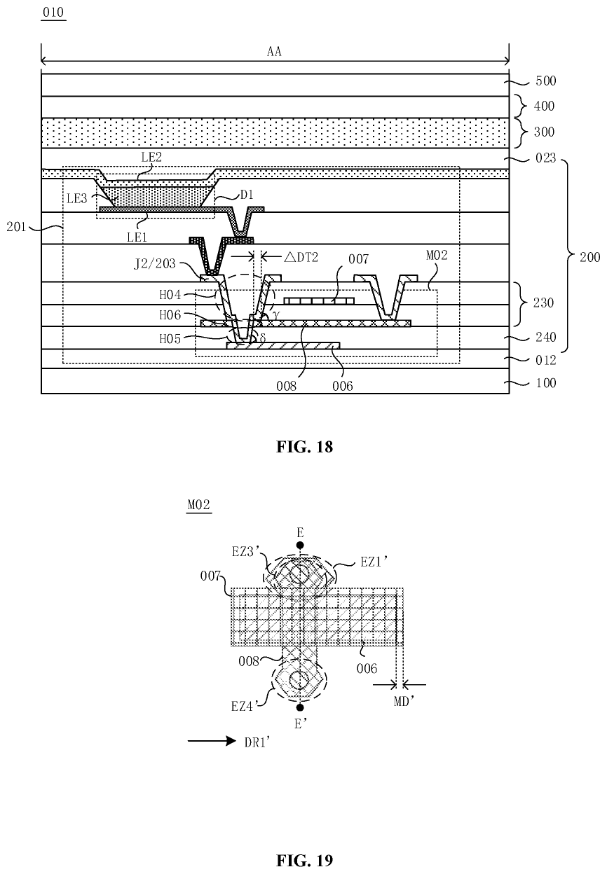

In an embodiment, FIG. 18 is an eighth schematic diagram of a film structure of a display panel according to an embodiment of the present application. Referring to FIG. 18, the circuit functional layer 200 further includes a third dielectric layer 230 between the second active structure 008 and the second conductive structure 203, and a fourth dielectric layer 240 between the third gate 006 and the second active structure 008. The third dielectric layer 230 includes a fourth etching hole H04, the fourth dielectric layer 240 includes a fifth etching hole H05, and the second active structure 008 includes a sixth etching hole H06. Along the direction perpendicular to the plane where the substrate 100 is located, the fourth etching hole H04, the fifth etching hole H05 and the sixth etching hole H06 overlap. The second connection portion J2 is provided in all of the fourth etching hole H04, the fifth etching hole H05 and the sixth etching hole H06.

In an embodiment, the second connection portion J2 can connect the second active structure 008 through the fourth etching hole H04, and the second connection portion J2 can also connect the third gate 006 through the fourth etching hole H04, the fifth etching hole H05 and the sixth etching hole H06. Along the direction perpendicular to the plane where the substrate 100 is located, the fourth etching hole H04, the fifth etching hole H05 and the sixth etching hole H06 overlap. The fourth etching hole H04, the fifth etching hole H05 and the sixth etching hole H06 can form a composite via hole penetrating through the third dielectric layer 230, the second active structure 008 and the third gate 006. In this way, it is beneficial to reduce the number of via holes in the third dielectric layer 230. There is no need to additionally provide a via hole for connecting the third gate 006 in the third dielectric layer 230, which is beneficial to reduce the space occupied by the pixel circuit 201, thereby improving the performance of the display panel 010.

Exemplarily, the sixth etching hole H06 can be formed in a process of forming the second active structure 008. When the surface of the third dielectric layer 230 is exposed and developed and the third dielectric layer 230 is etched to form the fourth etching hole H04, the fourth dielectric layer 240 between the second active structure 008 and the third gate 006 can also be etched through the sixth etching hole H06 of the second active structure 008 in the same process to form the fifth etching hole H05. The fourth etching hole H04 of the third dielectric layer 230 and the fifth etching hole H05 of the fourth dielectric layer 240 can be formed in the same process. On the one hand, it is beneficial to reduce the processes, and it is not necessary to form the fourth etching hole H04 and the fifth etching hole H05 in two separate processes, which is beneficial to improve the manufacturing efficiency and reduce the manufacturing cost. On the other hand, the process of forming the fifth etching hole H05 using the second active structure 008 as a mask can reduce the precision requirement in the manufacturing process. It is not necessary to consider the alignment problem between the sixth etching hole H06 and the fifth etching hole H05 of the fourth dielectric layer 240, which is beneficial to reduce the manufacturing difficulty and production cost. If the fourth etching hole H04 and the fifth etching hole H05 are formed in two separate processes, the precision requirement in the manufacturing process needs to be improved to ensure the alignment between the sixth etching hole H06 and the fifth etching hole H05.

In an embodiment, continuing to refer to FIG. 18, the diameter of the side of the fourth etching hole H04 close to the substrate 100 is smaller than or equal to the diameter of the side of the fourth etching hole H04 away from the substrate 100.

Exemplarily, along the direction perpendicular to the plane where the substrate 100 is located, the closer to the substrate 100, the smaller the diameter of the fourth etching hole H04. In this way, in a process of forming the second connection portion J2, the second connection portion J2 can be effectively attached to the sidewall of the fourth etching hole H04, improving the reliability of the connection between the second connection portion J2 and the third gate 006 and the connection between the second connection portion J2 and the second active structure 008.

On the basis of the above embodiment, continuing to refer to FIG. 18, an included angle γ, which is between the sidewall of the fourth etching hole H04 and the plane where the substrate 100 is located and faces the third dielectric layer 230, is smaller than or equal to 90°, which can ensure that the second connection portion J2 on the sidewall of the fourth etching hole H04 is not disconnected to avoid an open circuit.

In another embodiment, continuing to refer to FIG. 18, a diameter of a side of the fifth etching hole H05 close to the substrate 100 is smaller than or equal to a diameter of a side of the fifth etching hole H05 away from the substrate 100.

Exemplarily, along the direction perpendicular to the plane where the substrate 100 is located, the closer to the substrate 100, the smaller the diameter of the fifth etching hole H05. In this way, in a process of forming the second connection portion J2, the second connection portion J2 can be effectively attached to the sidewall of the fifth etching hole H05, improving the reliability of the connection between the second connection portion J2 and the third gate 006.

On the basis of the above embodiment, continuing to refer to FIG. 18, an included angle δ, which is between the sidewall of the fifth etching hole H05 and the plane where the substrate 100 is located and faces the fourth dielectric layer 240, is smaller than or equal to 90°, which can ensure that the second connection portion J2 on the sidewall of the fifth etching hole H05 will not be disconnected to avoid an open circuit.

In yet another optional embodiment, the minimum diameter of the sixth etching hole H06 is greater than or equal to 1.5 μm.

Exemplarily, along the direction perpendicular to the plane where the substrate 100 is located, the closer to the substrate 100, the smaller the diameter of the sixth etching hole H06. The minimum diameter of the sixth etching hole H06 is a diameter of a side of the sixth etching hole H06 closest to the substrate 100. The second active structure 008 can serve as a mask layer or protective layer for forming the fifth etching hole H05 below. By limiting the minimum diameter of the sixth etching hole H06 to be greater than or equal to 1.5 μm, the maximum diameter of the fifth etching hole H05 located below the sixth etching hole H06 can be limited. When the process for forming the fifth etching hole H05 is determined, the sidewall slope of the fifth etching hole H05 and the thickness of the fourth dielectric layer 240 can be determined. By limiting the minimum diameter of the sixth etching hole H06 (i.e., the maximum diameter of the fifth etching hole H05) to be greater than or equal to 1.5 μm, the minimum diameter of the fifth etching hole H05 can be determined, avoiding that the minimum diameter of the fifth etching hole H05 is too small or the third gate 006 located below the fifth etching hole H05 is not exposed, which affects the reliability of the contact connection between the second connection portion J2 and the third gate 006.

In still another embodiment, a diameter of a side of the fourth etching hole H04 closest to the substrate 100 is greater than a diameter of a side of the sixth etching hole H06 farthest from the substrate 100.

The minimum aperture of the fourth etching hole H04 is greater than the maximum aperture of the sixth etching hole H06, and the fourth etching hole H04 can completely cover the sixth etching hole H06 and expose a part of the second active structure 03′. In this way, when the second connection portion J2 is formed in the fourth etching hole H04, the fifth etching hole H05 and the sixth etching hole H06, the second connection portion J2 can be formed on a part of surface of the second active structure 03′ away from the substrate 100. Thus, the second connection portion J2 can be in contact connection with both the sidewall of the second active structure 03′ (i.e., the sidewall of the sixth etching hole H06) and the part of surface of the second active structure 03′ away from the substrate 100, which is beneficial to increase the contact area between the second connection portion J2 and the second active structure 03′, reduce the contact resistance, and increase the reliability of the connection between the second connection portion J2 and the second active structure 03′.

On the basis of the above embodiment, continuing to refer to FIG. 18, the distance between the edge of the fourth etching hole H04 closest to the substrate 100 and the edge of the sixth etching hole H06 farthest from the substrate 100 is ΔDT2, wherein ΔDT2 is greater than or equal to the thickness of the second active structure 03′, and smaller than or equal to 0.5 μm. By setting ΔDT 2 to be greater than or equal to the thickness of the second active structure 03′, the contact area between the second connection portion J2 and the surface of the second active structure 03′ away from the substrate 100 can be effectively increased, and the contact resistance can be reduced. In addition, ΔDT2≤0.5 μm is beneficial to reduce the area of the extension area of the second active structure 03′ and the aperture size of the fourth etching hole H04, thereby reducing the occupied space of the second transistor M02.

In an embodiment, FIG. 19 is a second schematic top view of a second transistor according to an embodiment of the present application, and the cross-sectional structure of the second transistor M02 along the dashed line E-E′ in FIG. 19 is shown in FIG. 21. Referring to FIG. 18 and FIG. 19, along the direction perpendicular to the plane where the substrate 100 is located, the third gate 006 and the fourth gate 007 overlap. A size of the third gate 006 in a fourth direction DR1′ is different from a size of the fourth gate 007 in the fourth direction DR1′. The fourth direction DR1′ is parallel to the plane where the substrate 100 is located.

The fourth direction DR1′ may intersect or be parallel to the first direction DR1 described above. An orientation of the fourth direction DR1′ is not particularly limited in the embodiments of the present application.

In an embodiment, both the third gate 006 and the fourth gate 007 include metal materials. Due to reasons such as geometric stress concentration and mismatch of mechanical properties between materials, the inorganic dielectric layer at step edges of the third gate 006 and the fourth gate 007 is prone to cracks, causing reliability problems. By setting the sizes of the third gate 006 and the fourth gate 007 of the second transistor M02 in the fourth direction DR1′ to be different, the unreliability caused by the crack effect at the step slope edges of the third gate 006 and the fourth gate 007 can be improved, avoiding that the crack effect at the step slope edges of the third gate 006 and the fourth gate 007 is superimposed in the longitudinal space, causing serious consequences and affecting the performance of the display panel 010.

In an embodiment, the orthographic projection of the third gate 006 on the plane where the substrate 100 is located is a third projection, and the orthographic projection of the fourth gate 007 on the plane where the substrate 100 is located is a fourth projection. In one second transistor M02, the minimum distance MD′ between the edge of the third projection and the edge of the fourth projection is greater than or equal to 0.5 μm. By limiting the minimum distance MD′ between the edge of the third projection and the edge of the fourth projection to be greater than or equal to 0.5 μm, the step slope edges of the third gate 006 and the fourth gate 007 can be arranged in a staggered manner in the longitudinal space, effectively improving the unreliability caused by the crack at the step slope edges of the third gate 006 and the fourth gate 007, and avoiding that the step slope edges of the third gate 006 and the fourth gate 007 are close to each other in the longitudinal space. The step slope edges close to each other may cause the crack effect of the third gate 006 and the fourth gate 007 to be superimposed in the longitudinal space and increase the unreliability.

In an embodiment, continuing to refer to FIG. 18 and FIG. 19, the size of the fourth gate 007 in the fourth direction DR1′ is greater than the size of the third gate 006 in the fourth direction DR1′. By increasing the size of the fourth gate 007 located above the third gate 006 in the fourth direction DR1′, it is beneficial to reduce the number of metal step slopes directly exposed to the light-emitting layer, the encapsulation layer and the touch layer, thereby reducing the influence of the crack effect of the inorganic dielectric layer on the film layers such as the electrode layer, the light-emitting layer, the encapsulation layer and the touch layer. In addition, the position of the step slope edge of the third gate 006 located below the fourth gate 007 is usually near the edge of the fourth gate 007 in the longitudinal space, and the distance between the overlapping third gate 006 and fourth gate 007 in the direction perpendicular to the plane where the substrate 100 is located is usually short in the longitudinal space. Therefore, the crack effect of the inorganic dielectric layer at the step slope edge of the third gate 006 located below the fourth gate 007 has a small influence on the fourth gate 007 located above the third gate 006.

In another embodiment, the fourth gate 007 includes a third deposition layer and a fourth deposition layer (not shown in FIG. 18 and FIG. 19). The third deposition layer is located on a side of the fourth deposition layer close to the substrate 100. Young's modulus of the third deposition layer is smaller than Young's modulus of the fourth deposition layer.

Materials with a small Young's modulus usually have better plasticity, are easier to be stretched and are not easy to break. By providing the third deposition layer with a small Young's modulus on the side of the fourth gate 007 close to the substrate 100, it is beneficial to reduce the influence of the crack effect at the step slope edge of the third gate 006 on the fourth gate 007. In addition, only providing the first deposition layer DL1 in the fourth gate 007, which is located above the third gate 006, is beneficial to reduce the manufacturing processes and reduce the manufacturing cost.

In an embodiment, the third gate 006 and the fourth deposition layer may include molybdenum (Mo) metal. The third deposition layer may include titanium (Ti) material. In one embodiment, if the pixel circuit 201 further includes the first transistor M01 and the second gate 002 of the first transistor M01 includes the first deposition layer DL1 and the second deposition layer DL2, the third deposition layer of the fourth gate 007 can be formed in the same process as the first deposition layer DL1 of the second gate 002, and the fourth deposition layer of the fourth gate 007 can be formed in the same process as the second deposition layer DL2 of the second gate 002.

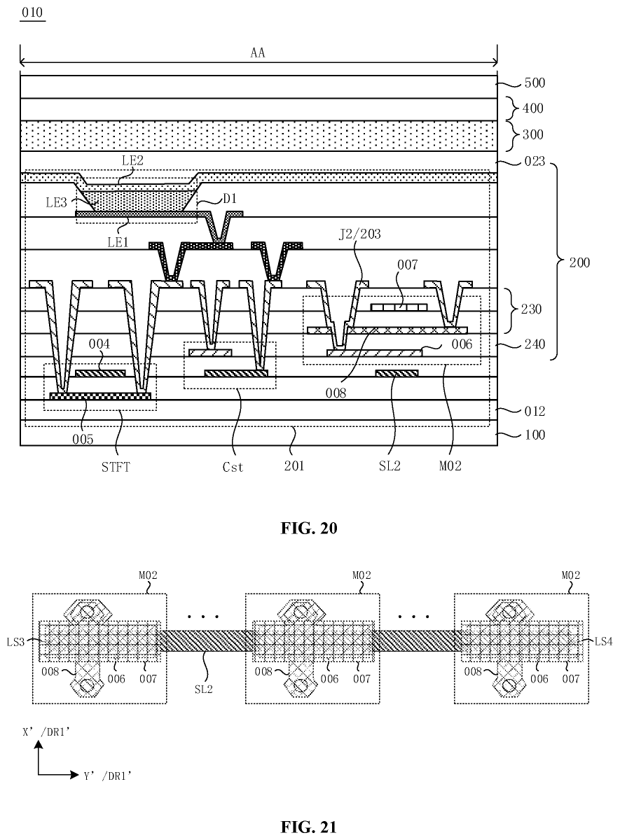

In an embodiment, FIG. 20 is a ninth schematic diagram of a film structure of a display panel according to an embodiment of the present application, and FIG. 21 is a third schematic top view of a second transistor according to an embodiment of the present application. Referring to FIG. 20 and FIG. 21, the circuit functional layer 200 further includes a second signal line SL2 on a side of the second transistor M02 close to the substrate 100. The second signal line SL2 is electrically connected to multiple pixel circuits 201 in one row (not shown in FIG. 20 and FIG. 21). Along the direction perpendicular to the plane where the substrate 100 is located, the second signal line SL2 overlaps both the third gates 006 and the fourth gates 007 of multiple second transistors M02.

The second signal line SL2 is used to transmit an electrical signal and provide the electrical signal to the pixel circuits 201. In one embodiment, the second signal line SL2 extends along the row direction, and is used to transmit signals such as a write control signal S2P, a compensation control signal S2N, an initialization control signal S1N, and a reset control signal S1P. In another embodiment, the second signal line SL2 extends along the column direction, and is used to transmit signals such as a write data signal Data, an initialization signal VREF1, and a reset signal VREF2. If the circuit functional layer 200 further includes the first signal line SL1 described above, the second signal line SL2 and the first signal line SL1 described above may be the same signal line, or different signal lines, which will not be limited by the embodiments of the present application.

In an embodiment, taking a case where the second signal line SL2 is electrically connected to the gates of other transistors in the pixel circuit 201 except the second transistor M02 and the second signal line SL2 can provide a gate driving signal to the gates of other transistors as an example, referring to FIG. 20, at least part of the switching transistors STFT in the pixel circuit 201 are not set as the second transistor M02. This part of the switching transistors STFT include a switching gate 004 and a switching active structure 005. The switching gate 004 and the switching active structure 005 can both be located on a side of the second transistor M02 close to the substrate 100. In one embodiment, the second signal line SL2 can be arranged in the same layer as the switching gate 004. On this basis, the switching gate 004 can also reuse the second signal line SL2 (not shown in FIG. 20).

Continuing to refer to FIG. 20 and FIG. 21, the second signal line SL2 is located on the side of the second transistor M02 close to the substrate 100, which can reduce the influence of the crack effect of the third gate 006 and the fourth gate 007 of the second transistor M02, and avoid that the crack effect of the third gate 006 and/or the fourth gate 007 causes the breakage of the second signal line SL2 and affects the electrical connection of the second signal line SL2. In addition, along the direction perpendicular to the plane where the substrate 100 is located, the second signal line SL2 overlaps both the third gates 006 and the fourth gates 007 of multiple second transistors M02, which can save the space of the circuit functional layer 200, increase the light transmittance, and is also beneficial to the high resolution and thinning of the display panel 010. In one embodiment, the size of the second signal line SL2 in the fourth direction DR1′ is different from the size of the fourth gate 007 in the fourth direction DR1′, and/or, the size of the second signal line SL2 in the fourth direction DR1′ is different from the size of the third gate 006 in the fourth direction DR1′, to avoid that the crack effect at the step slope edge of the second signal line SL2 is superimposed in the longitudinal space, causing serious consequences and affecting the performance of the display panel 010.

In an embodiment, continuing to refer to FIG. 21, a size of the second signal line SL2 in a fifth direction X′ is smaller than a size of the fourth gate 007 in the fifth direction X′. The fifth direction X′ is parallel to the plane where the substrate 100 is located, and intersects an extension direction of the second signal line SL2.

In an embodiment, the second signal line SL2 extends along the row direction, and the fifth direction X′ may be the column direction. The second signal line SL2 can be electrically connected to multiple pixel circuits 201 in the same row. Along the extension direction of the second signal line SL2, the size of the second signal line SL2 is usually larger than the size of the fourth gate 007. By setting the size of the second signal line SL2 in the fifth direction X′ to be smaller than the size of the fourth gate 007 in the fifth direction X′, it is beneficial to reduce the number of metal step slopes directly exposed to the light-emitting layer, the encapsulation layer and the touch layer, thereby reducing the influence of the crack effect of the inorganic dielectric layer on the film layers such as the electrode layer, the light-emitting layer, the encapsulation layer and the touch layer.

In other implementations, the second signal line may also extend along the column direction, and the fifth direction may also be the row direction.

In one embodiment, if the circuit functional layer 200 further includes the first signal line SL1 described above, the extension direction of the second signal line SL2 is the same as the extension direction of the first signal line SL1, and the fifth direction X′ may be parallel to the second direction X. In another embodiment, the extension direction of the second signal line SL2 intersects the extension direction of the first signal line SL1, and the fifth direction X′ may intersect the second direction X.

In another embodiment, continuing to refer to FIG. 21, a size of the second signal line SL2 in the fifth direction X′ is smaller than a size of the third gate 006 in the fifth direction X'. The fifth direction X′ is parallel to the plane where the substrate 100 is located, and intersects the extension direction of the second signal line SL2. This arrangement is also beneficial to reduce the number of metal step slopes directly exposed to the light-emitting layer, the encapsulation layer and the touch layer, thereby reducing the influence of the crack effect of the inorganic dielectric layer on the film layers such as the electrode layer, the light-emitting layer, the encapsulation layer and the touch layer.

In yet another embodiment, the second signal line SL2 includes a third edge LS3, and a fourth edge LS4 opposite to the third edge LS3 along a sixth direction Y′. The sixth direction Y′ is parallel to the extension direction of the second signal line SL2. The orthographic projection of the third gate 006 on the plane where the substrate 100 is located is a third projection, and the orthographic projection of the fourth gate 007 on the plane where the substrate 100 is located is a fourth projection. The orthographic projections of the third edge LS3 and the fourth edge LS4 on the plane where the substrate 100 is located are covered by the third projection, and the minimum distance between the third edge LS3 and the edge of the third projection and the minimum distance between the fourth edge LS4 and the edge of the third projection are both greater than zero; and/or, the orthographic projections of the third edge LS3 and the fourth edge LS4 on the plane where the substrate 100 is located are covered by the fourth projection, and the minimum distance between the third edge LS3 and the edge of the fourth projection and the minimum distance between the fourth edge LS4 and the edge of the fourth projection are both greater than zero.

In an embodiment, the third edge LS3 and the fourth edge LS4 both overlap the third gate 006 along the direction perpendicular to the plane where the substrate 100 is located, and along the direction perpendicular to the plane where the substrate 100 is located, the distance between the third edge LS3 and the edge of the third gate 006 and the distance between the fourth edge LS4 and the edge of the third gate 006 are both greater than zero; and/or the third edge LS3 and the fourth edge LS4 both overlap the fourth gate 007 along the direction perpendicular to the plane where the substrate 100 is located, and along the direction perpendicular to the plane where the substrate 100 is located, the distance between the third edge LS3 and the edge of the fourth gate 007 and the distance between the fourth edge LS4 and the edge of the fourth gate 007 are both greater than zero. In the longitudinal space (the direction perpendicular to the plane where the substrate 100 is located), the third edge LS3 and the fourth edge LS4 are retracted relative to the edge of the third gate 006 towards the center area of the second signal line SL2 and/or the third gate 006; and/or, in the longitudinal space (the direction perpendicular to the plane where the substrate 100 is located), the third edge LS3 and the fourth edge LS4 are retracted relative to the edge of the fourth gate 007 towards the center area of the second signal line SL2 and/or the fourth gate 007. This arrangement is beneficial to reduce the number of metal step slopes directly exposed to the side away from the substrate 100, reduce the influence of the crack effect of the inorganic dielectric layer, and improve the reliability of the display panel 010.

In an embodiment, the second signal line SL2 can run through the display area AA in the sixth direction Y′ (the row direction) and connect all the pixel circuits 201 in the same row. Although the size of the second signal line SL2 is larger than the size of the third gate 006 along the sixth direction Y′ (the row direction), the third edge LS3 and the fourth edge LS4 of the second signal line SL2 are retracted relative to the third gates 006 of two second transistors M02 at the outermost sides among all the pixel circuits 201 in the same row; and/or the third edge LS3 and the fourth edge LS4 of the second signal line SL2 are retracted relative to the fourth gates 007 of two second transistors M02 at the outermost sides among all the pixel circuits 201 in the same row. This arrangement can avoid the crack effect of the third edge LS3 and/or the fourth edge LS4 affecting the film structure on the side of the second transistor M02 away from the substrate 100. The crack effect of the third edge LS3 and the fourth edge LS4 has a small influence on the third gate 006 and the fourth gate 007 of the second transistor M02. Even if the crack effect affects the third gate 006 and the fourth gate 007, it only affects the structural integrity near the edges of the third gate 006 and the fourth gate 007, and does not affect the core areas of the third gate 006 and the fourth gate 007.

In other implementations, the second signal line can run through the display area AA in the sixth direction (the column direction) and connect all the pixel circuits 201 in the same column.

In one embodiment, if the circuit functional layer 200 further includes the first signal line SL1 described above, the extension direction of the second signal line SL2 is the same as the extension direction of the first signal line SL1, and the sixth direction Y′ may be parallel to the third direction Y. In another embodiment, the extension direction of the second signal line SL2 intersects the extension direction of the first signal line SL1, and the sixth direction Y′ may intersect the third direction Y.

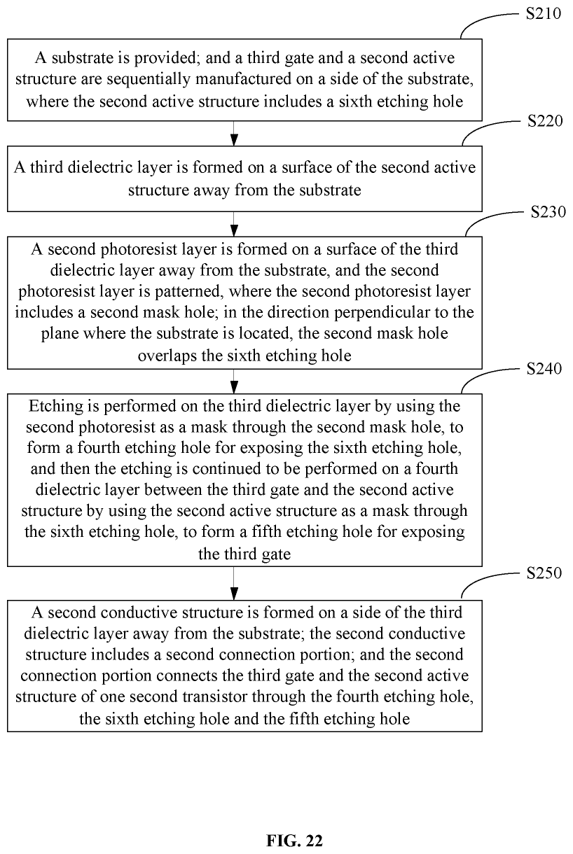

Based on the same inventive concept, a method for manufacturing a display panel is further provided according to an embodiment of the present application, which is used to manufacture the display panel shown in FIG. 14, FIG. 16, FIG. 18, and FIG. 20. FIG. 22 is a second flowchart of a method for manufacturing a display panel according to an embodiment of the present application. Referring to FIG. 22, the method includes S210 to S250.

In S210, a substrate is provided; and a third gate and a second active structure are sequentially manufactured on a side of the substrate. The second active structure includes a sixth etching hole.

Exemplarily, referring to FIG. 14, FIG. 16, FIG. 18 and FIG. 20, before the third gate 006 and the second active structure 008 is manufactured on the side of the substrate 100, structures such as a protective layer 012, a photosensitive layer 260, a switching active structure 005, a switching gate 004, a second signal line SL2, and dielectric layers arranged adjacent to these structures can be selectively formed. Then, the third gate 006 is formed first, and then the second active structure 008 is formed. In one embodiment, the sixth etching hole H06 can be formed during forming the second active structure 008.

In S220, a third dielectric layer is formed on a surface of the second active structure away from the substrate.

In an embodiment, after the second active structure 008 is formed, a third dielectric layer 230 can be formed on the surface of the second active structure 008 away from the substrate 100. The third dielectric layer 230 can fill and cover the sixth etching hole H06.

In S230, a second photoresist layer is formed on a surface of the third dielectric layer away from the substrate, and the second photoresist layer is patterned. The second photoresist layer includes a second mask hole. In the direction perpendicular to the plane where the substrate is located, the second mask hole overlaps the sixth etching hole.

In an embodiment, a photolithography process can be used to pattern the entire layer of the third dielectric layer 230. In one embodiment, the minimum diameter of the second mask hole is larger than the maximum diameter of the sixth etching hole H06.

In S240, etching is performed on the third dielectric layer by using the second photoresist as a mask through the second mask hole, to form a fourth etching hole for exposing the sixth etching hole, and then the etching is continued to be performed on a fourth dielectric layer between the third gate and the second active structure by using the second active structure as a mask through the sixth etching hole, to form a fifth etching hole for exposing the third gate.

In an embodiment, the fourth etching hole H04 in the third dielectric layer 230 is formed in an etching process. After the fourth etching hole H04 is formed by etching, the etching can be continued. The fourth dielectric layer 240 between the third gate 006 and the second active structure 008 is continued to be etched by using the second active structure 008 as a mask, to form the fifth etching hole H05 for exposing the third gate 006. In one embodiment, the fourth etching hole H04 and the fifth etching hole H05 can be formed by one etching process.

In S250, a second conductive structure is formed on a side of the third dielectric layer away from the substrate. The second conductive structure includes a second connection portion, and the second connection portion connects the third gate and the second active structure of one second transistor through the fourth etching hole, the sixth etching hole and the fifth etching hole.

In an embodiment, after the fourth etching hole H04 and the fifth etching hole H05 are formed, an entire layer of a conductive layer can be formed on the surface of the third dielectric layer 230 away from the substrate 100. The conductive layer can form on the surface of the third dielectric layer 230 away from the substrate 100, and the conductive layer can also be formed on the sidewalls of the fourth etching hole H04, the sixth etching hole H06 and the fifth etching hole H05, and the exposed surface of the third gate 006 away from the substrate 100. Then, the conductive layer is patterned to obtain the second conductive structure 203 that connects both the third gate 006 and the second active structure 008.

In the embodiments of the present application, the fourth etching hole of the third dielectric layer and the fifth etching hole of the fourth dielectric layer can be formed in the same process, which is beneficial to reduce the processes. It is not necessary to form the fourth etching hole and the fifth etching hole in two separate processes, which is beneficial to improve the manufacturing efficiency and reduce the manufacturing cost. In addition, the fifth etching hole is formed by using the second active as a mask, which can reduce the precision requirement in the manufacturing process. It is not necessary to consider the alignment problem between the sixth etching hole and the fifth etching hole of the fourth dielectric layer, which is beneficial to reduce the manufacturing difficulty and production cost.

In an embodiment, the circuit functional layer 200 further includes a first conductive structure 202, and the first conductive structure 202 and the second conductive structure 203 can be arranged in the same layer and formed in the same process.

In another embodiment, the pixel circuit 201 further includes the first transistor M01. The first active structure 003 of the first transistor M01 and the second active structure 008 of the second transistor M02 include the same material, and the first active structure 003 and the second active structure 008 can be arranged in the same layer and formed in the same process. In one embodiment, the first gate 001 and the third gate 006 can be arranged in the same layer and formed in the same process. In another embodiment, the second gate 002 and the fourth gate 007 can be arranged in the same layer and formed in the same process.

The method for manufacturing the display panel according to the embodiments of the present application is used to manufacture the display panel according to the above embodiments of the present application, and has corresponding technical features and beneficial effects of the display panel. For the content not described in detail in the embodiments of the method for manufacturing the display panel, reference can be made to the above description of the display panel, and will not be repeated here. Similarly, the display panel of the embodiments of the present application also has the functional modules and beneficial effects for executing the method for manufacturing the display panel according to the embodiments of the present application. For the content not described in detail in the embodiments of the display panel, reference can be made to the above description of the method for manufacturing a display panel, and will not be repeated here.

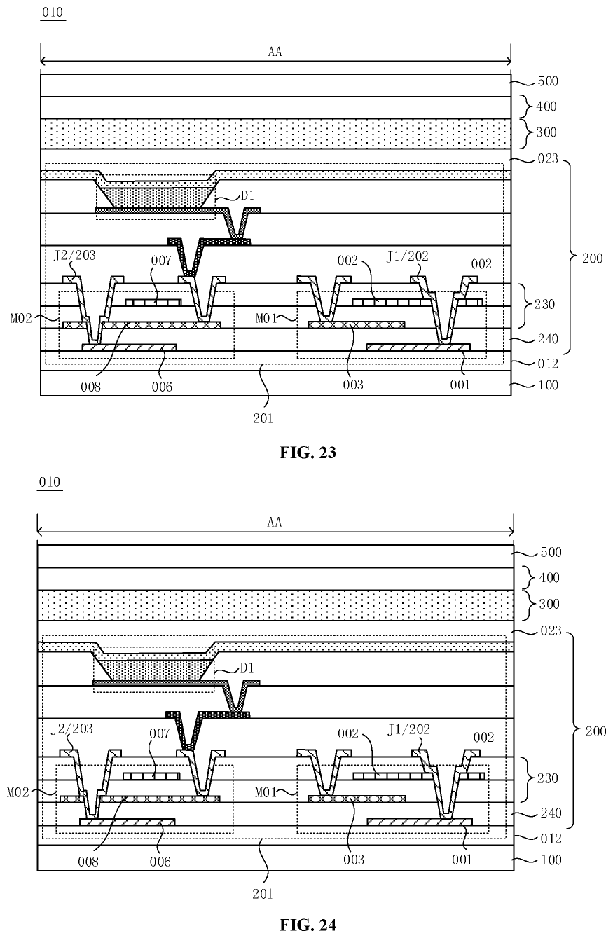

In addition to the display panel 010 as shown above, the display panel 010 may be implemented in other implementations. FIG. 23 is a tenth schematic diagram of a film structure of a display panel according to an embodiment of the present application. Referring to FIG. 23, at least part of the pixel circuits 201 can include both the first transistor M01 and the second transistor M02. The first gate 001 and the second gate 002 of the first transistor M01 can connect the first connection portion J1 of the first conductive structure 202; and the third gate 006 and the second active structure 008 of the second transistor M02 can be electrically connected to the second connection portion J2 of the second conductive structure 203.

In an embodiment, at least part of the switching transistors in the pixel circuit 201 can be set as the first transistor M01, and the potential of the first gate 001 and the potential of the second gate 002 thereof are the same, which is beneficial to increase the on-state current of the switching transistor and improve the switching speed. The driving transistor in the pixel circuit 201 can be set as the second transistor M02, and the potential of the third gate 006 and the potential of the source area or the drain area of the second active structure 008 thereof are the same, which is beneficial to suppress the threshold voltage shift of the driving transistor, improve its working stability, extend its service life, and thus improve the display effect and reliability of the display panel 010.

In one embodiment, continuing to refer to FIG. 23, a part of the structure in the first transistor M01 and a part of the structure in the second transistor M02 can be arranged in the same layer and formed in the same process. In another embodiment, FIG. 24 is an eleventh schematic diagram of a film structure of a display panel according to an embodiment of the present application. Referring to FIG. 24, the structure in the first transistor M01 can also be formed in a different process from all the structures in the second transistor M02.

The above content only exemplarily shows some implementations of the display panel, and the film structure of the display panel according to the present application is not limited to the above structures. Any transistor in the pixel circuit can be set as the first transistor or the second transistor, and the first transistor and the second transistor can be located at the same or different film layer. Under the condition of no contradiction, different implementations can be combined with each other.

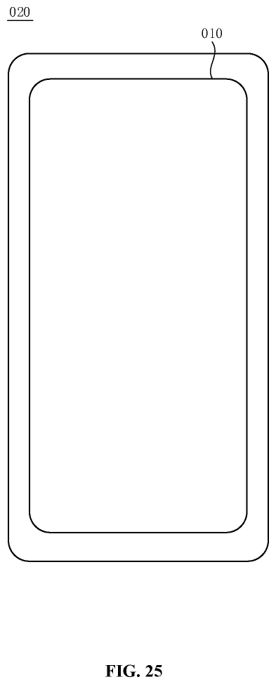

Based on the same inventive concept, a display device is further provided according to an embodiment of the present application. FIG. 25 is a schematic structural diagram of a display device according to an embodiment of the present application. As shown in FIG. 25, the display device 020 includes the display panel 010 according to any embodiment of the present application. The display device 020 according to the embodiment of the present application can be the mobile phone shown in FIG. 25, or any electronic product with a display function, including but not limited to the following categories: a television, a notebook computer, a desktop monitor, a tablet computer, a digital camera, a smart bracelet, smart glasses, a vehicle-mounted display, medical equipment, industrial control equipment, a touch interactive terminal, etc., which will not be limited by the embodiments of the present application.

Note that the above are only the preferred embodiments of the present application and the applied technical principles. It should be understood that the present application is not limited to the specific embodiments described here, and various changes, readjustments and substitutions can be made in the art without departing from the protection scope of the present application. Therefore, although the present application has been described in more detail through the above embodiments, the present application is not limited to the above embodiments, and without departing from the concept of the present application, it can also include other equivalent embodiments, and the scope of the present application is determined by the appended claims.

1. A display panel, comprising:
a substrate; and
a circuit functional layer on a side of the substrate,
wherein the circuit functional layer comprises a plurality of pixel circuits in a display area;
at least part of the plurality of pixel circuits comprises a transistor and a light-emitting element;
the transistor comprises an active structure, a first gate and a second gate, the first gate is located on a side of the active structure close to the substrate, and the second gate is located on a side of the active structure away from the substrate;
the circuit functional layer further comprises conductive structures on a side of the second gate away from the substrate; and
wherein a conductive structure of the conductive structures comprises a connection portion; and
wherein along a direction perpendicular to a plane where the substrate is located, the connection portion overlaps an overlapping area of the first gate and the second gate of one transistor, and the connection portion connects the first gate and the second gate of the one transistor; or wherein along a direction perpendicular to a plane where the substrate is located, the connection portion overlaps an overlapping area of the first gate and the active structure of one transistor, and the connection portion connects the first gate and the active structure of the one transistor.

2. The display panel according to claim 1, wherein the transistor comprises a driving transistor and/or a switching transistor;
the driving transistor is configured to selectively provide a driving signal to the light-emitting element; and
the switching transistor is configured to selectively provide an electrical signal to the driving transistor and/or the light-emitting element.

3. The display panel according to claim 1, wherein the active structure of the transistor comprises a metal oxide material, and the first active structure of the first transistor is linear shaped.

4. The display panel according to claim 1, wherein
the circuit functional layer further comprises a first dielectric layer between the second gate and the conductive structure, and a second dielectric layer between the first gate and the second gate;
the first dielectric layer comprises a first etching hole, the second dielectric layer comprises a second etching hole, and the second gate comprises a third etching hole; and
wherein along the direction perpendicular to the plane where the substrate is located, the first etching hole, the second etching hole, and the third etching hole overlap; the connection portion is provided in the first etching hole, the second etching hole and the third etching hole.

5. The display panel according to claim 4, wherein a diameter of a side of the first etching hole close to the substrate is smaller than or equal to a diameter of a side of the first etching hole away from the substrate; and/or
a diameter of a side of the second etching hole close to the substrate is smaller than or equal to a diameter of a side of the second etching hole away from the substrate.

6. The display panel according to claim 4, wherein
an included angle which is between a sidewall of the first etching hole and the plane where the substrate is located and faces the first dielectric layer is smaller than or equal to 90°; and/or an included angle which is between a sidewall of the second etching hole and the plane where the substrate is located and faces the second dielectric layer is smaller than or equal to 90°, and
wherein a minimum diameter of the third etching hole is greater than or equal to 1.5 μm.

7. The display panel according to claim 4, wherein a diameter of a side of the first etching hole closest to the substrate is greater than a diameter of a side of the third etching hole farthest from the substrate, and
a distance between an edge of the first etching hole closest to the substrate and an edge of the third etching hole farthest from the substrate is ΔDT1, wherein ΔDT1 is greater than or equal to a thickness of the second gate, and smaller than or equal to 0.5 μm.

8. The display panel according to claim 1, wherein along the direction perpendicular to the plane where the substrate is located, the first gate and the second gate overlap; and
a size of the first gate in a first direction is different from a size of the second gate in the first direction, wherein the first direction is parallel to the plane where the substrate is located.

9. The display panel according to claim 8, wherein the size of the second gate in the first direction is greater than the size of the first gate in the first direction.

10. The display panel according to claim 8, wherein the second gate comprises a first deposition layer and a second deposition layer;
wherein the first deposition layer is located on a side of the second deposition layer close to the substrate, and Young's modulus of the first deposition layer is smaller than Young's modulus of the second deposition layer.

11. The display panel according to claim 8, wherein the circuit functional layer further comprises a signal line on a side of the transistor close to the substrate, the signal line is electrically connected to the plurality of pixel circuits; and
along the direction perpendicular to the plane where the substrate is located, the signal line overlaps the first gates and the second gates of a plurality of transistors.

12. The display panel according to claim 11, wherein a size of the signal line in a second direction is smaller than a size of the second gate in the second direction, wherein the second direction is parallel to the plane where the substrate is located, and intersects an extension direction of the signal line; and/or
a size of the signal line in a second direction is smaller than a size of the first gate in the second direction, wherein the second direction is parallel to the plane where the substrate is located, and intersects an extension direction of the signal line.

13. The display panel according to claim 11, wherein
the signal line comprises a first edge and a second edge which are oppositely arranged along a third direction, wherein the third direction is parallel to an extension direction of the signal line;
an orthographic projection of the first gate on the plane where the substrate is located is a first projection, and an orthographic projection of the second gate on the plane where the substrate is located is a second projection; and
orthographic projections of the first edge and the second edge on the plane where the substrate is located are covered by the first projection, and a minimum distance between the first edge and an edge of the first projection and a minimum distance between the second edge and the edge of the first projection are both greater than zero; and/or, orthographic projections of the first edge and the second edge on the plane where the substrate is located are covered by the second projection, and a minimum distance between the first edge and an edge of the second projection and a minimum distance between the second edge and the edge of the second projection are both greater than zero.

14. The display panel according to claim 1, wherein
an orthographic projection of the first gate on the plane where the substrate is located is a first projection, an orthographic projection of the second gate on the plane where the substrate is located is a second projection, and
a minimum distance between an edge of the first projection and an edge of the second projection is greater than or equal to 0.5 μm.

15. The display panel according to claim 1, wherein the display area comprises: a functional device arrangement area, and a main display area at least partially surrounding the functional device arrangement area; the functional device arrangement area comprises the plurality of pixel circuits and a functional device located on a side of the plurality of pixel circuits close to the substrate; and
the circuit functional layer in the functional device arrangement area comprises the transistor, and the conductive structure connecting the first gate and the second gate of the transistor.

16. The display panel according to claim 1, wherein
the circuit functional layer further comprises a third dielectric layer between the active structure and the conductive structure, and a fourth dielectric layer between the first gate and the active structure;
the third dielectric layer comprises a fourth etching hole, the fourth dielectric layer comprises a fifth etching hole, and the active structure comprises a sixth etching hole; and
wherein along the direction perpendicular to the plane where the substrate is located, the fourth etching hole, the fifth etching hole, and the sixth etching hole overlap; the second connection portion is provided in the fourth etching hole, the fifth etching hole and the sixth etching hole.

17. The display panel according to claim 16, wherein a diameter of a side of the fourth etching hole close to the substrate is smaller than or equal to a diameter of a side of the fourth etching hole away from the substrate; and/or
a diameter of a side of the fifth etching hole close to the substrate is smaller than or equal to a diameter of a side of the fifth etching hole away from the substrate.

18. The display panel according to claim 16, wherein
an included angle which is between a sidewall of the fourth etching hole and the plane where the substrate is located and faces the third dielectric layer is smaller than or equal to 90°; and/or an included angle which is between a sidewall of the fifth etching hole and the plane where the substrate is located and faces the fourth dielectric layer is smaller than or equal to 90°, and
wherein a minimum diameter of the sixth etching hole is greater than or equal to 1.5 μm.

19. The display panel according to claim 16, wherein a diameter of a side of the fourth etching hole closest to the substrate is greater than a diameter of a side of the sixth etching hole farthest from the substrate, and
a distance between an edge of the fourth etching hole closest to the substrate and an edge of the sixth etching hole farthest from the substrate is ΔDT2, wherein ΔDT2 is greater than or equal to a thickness of the active structure, and smaller than or equal to 0.5 μm.

20. A display device, comprising: the display panel according to claim 1.
